(19) United States
(12) Patent Application Publication
(10) Pub. No.: US 2022/0165874 A1
(43) Pub. Date: May 26, 2022

(54) NITRIDE SEMICONDUCTOR DEVICE

(71) Applicant: ROHM CO., LTD., Kyoto-shi (JP)

(72) Inventor: Hirotaka OTAKE, Kyoto-shi (JP)

(21) Appl. No.: 17/456,282

(22) Filed: Nov. 23, 2021

(30) Foreign Application Priority Data
Nov. 26, 2020 (JP) 2020-196156

(51) Int. Cl. H01L 29/778; H01L 29/20; H01L 29/43

(52) U.S. Cl. CPC H01L 29/7786; H01L 29/432; H01L 29/2003

(57) ABSTRACT

A nitride semiconductor device includes an electron transfer layer formed from a nitride semiconductor, an electron supplying layer formed from a nitride semiconductor having a larger band gap than the electron transfer layer on the electron transfer layer, a first step layer formed from a nitride semiconductor having a smaller band gap than the electron supplying layer on part of the electron supplying layer, a second step layer formed from a nitride semiconductor having a larger band gap than the first step layer on the first step layer, a gate layer including an acceptor impurity and formed from a nitride semiconductor having a smaller band gap than the second step layer on the second step layer, a gate electrode formed on the gate layer, and a source electrode and a drain electrode. The first step layer includes a first extension extending outward from the gate layer in plan view.

### BACKGROUND

### 1. Field

The following description relates to a nitride semiconductor device.

### 2. Description of Related Art

High Electron Mobility Transistors (HEMTs) that use nitride semiconductor as the main material of an active region are being applied to power devices. A nitride semiconductor is a semiconductor that uses nitrogen as a group V element in a III-V semiconductor compound. In comparison with typical silicon carbide (SiC) power devices, power devices using nitride semiconductor are operable at higher speeds and higher frequencies. Nitride semiconductor devices also have the same low ON resistance characteristic as SiC power devices.

A power transistor such as a HEMT is required to be normally off so that a current path (channel) between the source and drain is cut off at zero-bias, in which a gate voltage is not applied, for fail-safe reasons. Japanese Laid-Open Patent Publication No. 2017-73506 describes a nitride semiconductor device that forms a normally-off power transistor.

The nitride semiconductor device described in Japanese Laid-Open Patent Publication No. 2017-73506 includes a heterojunction of a gallium nitride (GaN) layer, which is referred to as an electron transfer layer, and an aluminum gallium nitride (AlGaN) layer, which is formed on the electron transfer layer and referred to as an electron supplying layer. A two-dimensional electron gas (2DEG) is formed as a channel in the electron transfer layer in the vicinity of the heterojunction interface between the electron transfer layer and the electron supplying layer. A GaN layer (p-type GaN layer) doped with an acceptor impurity is arranged on the electron supplying layer underneath the gate electrode. The acceptor impurity in the p-type GaN layer disperses the channel of the electron transfer layer in the region underneath the gate electrode to obtain the normally-off characteristic. The application of a proper ON voltage to the gate electrode induces the channel of the electron transfer layer in the region underneath the gate electrode to electrically connect the source and drain.

In the structure such as that described in Japanese Laid-Open Patent Publication No. 2017-73506, the gate electrode and the p-type GaN layer form a Schottky-junction. An interface between the gate electrode and the p-type GaN layer form an energy barrier. The energy barrier sets the gate withstand voltage together with an energy barrier of the electron supplying layer. In such a structure, the application of a large positive bias to the gate electrode may increase gate leakage current. For example, when an external factor such as parasitic inductance results in the positive bias applied to the gate electrode being excessive, holes are injected into the p-type GaN layer from the gate electrode and accumulated in the interface between the p-type GaN layer and the electron supplying layer. The hole accumulation causes band bending of the electron supplying layer that results in the movement of electrons (electron leakage) from the electron transfer layer to the p-type GaN layer via the electron supplying layer. Such electron leakage increases the gate leak current and decreases the gate withstand voltage.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

A nitride semiconductor device according to one aspect of the present disclosure includes an electron transfer layer formed from a nitride semiconductor and an electron supplying layer formed on the electron transfer layer. The electron supplying layer is formed from a nitride semiconductor having a band gap that is larger than that of the electron transfer layer. The nitride semiconductor device also includes a first step layer formed on part of the electron supplying layer and a second step layer formed on the first step layer. The first step layer is formed from a nitride semiconductor having a band gap that is smaller than that of the electron supplying layer. The second step layer is formed from a nitride semiconductor having a band gap that is larger than that of the first step layer. The nitride semiconductor device also includes a gate layer formed on part of the second step layer. The gate layer is formed from a nitride semiconductor having a band gap that is smaller than that of the second step layer and includes an acceptor impurity. The nitride semiconductor device further includes a gate electrode formed on the gate layer, and a source electrode and a drain electrode that are in contact with the electron supplying layer. The first step layer includes a first extension that extends outward from the gate layer in plan view.

According to the nitride semiconductor device of this disclosure, the gate leak current is decreased and the gate withstand voltage is increased.

Other features and aspects will be apparent from the following detailed description, the drawings, and the claims.

### BRIEF DESCRIPTION OF THE DRAWINGS

FIG. 1 is a schematic cross-sectional view illustrating an example nitride semiconductor device in accordance with a first embodiment.

FIG. 2 is an enlarged cross-sectional view illustrating part of the nitride semiconductor device illustrated in FIG. 1.

FIG. 3 is a schematic cross-sectional view illustrating an example manufacturing step of the nitride semiconductor device illustrated in FIG. 1.

FIG. 4 is a schematic cross-sectional view illustrating an example manufacturing step following the step illustrated in FIG. 3.

FIG. 5 is a schematic cross-sectional view illustrating an example manufacturing step following the step illustrated in FIG. 4.

FIG. 6 is a schematic cross-sectional view illustrating an example manufacturing step following the step illustrated in FIG. 5.

FIG. 7 is a schematic cross-sectional view illustrating an example manufacturing step following the step illustrated in FIG. 6.

FIG. 8 is a schematic cross-sectional view illustrating an example manufacturing step following the step illustrated in FIG. 7.

FIG. 9 is a schematic cross-sectional view illustrating an example manufacturing step following the step illustrated in FIG. 8.

FIG. 10 is a schematic cross-sectional view illustrating an example nitride semiconductor device in accordance with a second embodiment.

FIG. 11 is a schematic cross-sectional view illustrating an example nitride semiconductor device in accordance with a third embodiment.

FIG. 12 is a schematic cross-sectional view illustrating an example nitride semiconductor device in accordance with a fourth embodiment.

FIG. 13 is a schematic cross-sectional view illustrating an example nitride semiconductor device in accordance with a fifth embodiment.

FIG. 14 is a schematic plan view illustrating an example formation pattern of the nitride semiconductor device illustrated in FIG. 1.

FIG. 15 is a schematic cross-sectional view of an active region taken along line F15-F15 in FIG. 14.

FIG. 16 is a schematic cross-sectional view of a non-active region taken along line F16-F16 in FIG. 14.

FIG. 17 is a schematic plan view illustrating another example formation pattern of the nitride semiconductor device illustrated in FIG. 1.

FIG. 18 is a schematic cross-sectional view of an active region taken along line F18-F18 in FIG. 17.

Throughout the drawings and the detailed description, the same reference characters refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Embodiments of a nitride semiconductor device will now be described with reference to the drawings.

In the drawings, elements are illustrated for simplicity and clarity and have not necessarily been drawn to scale. To facilitate understanding, hatching lines may not be illustrated in the cross-sectional drawings.

### First Embodiment

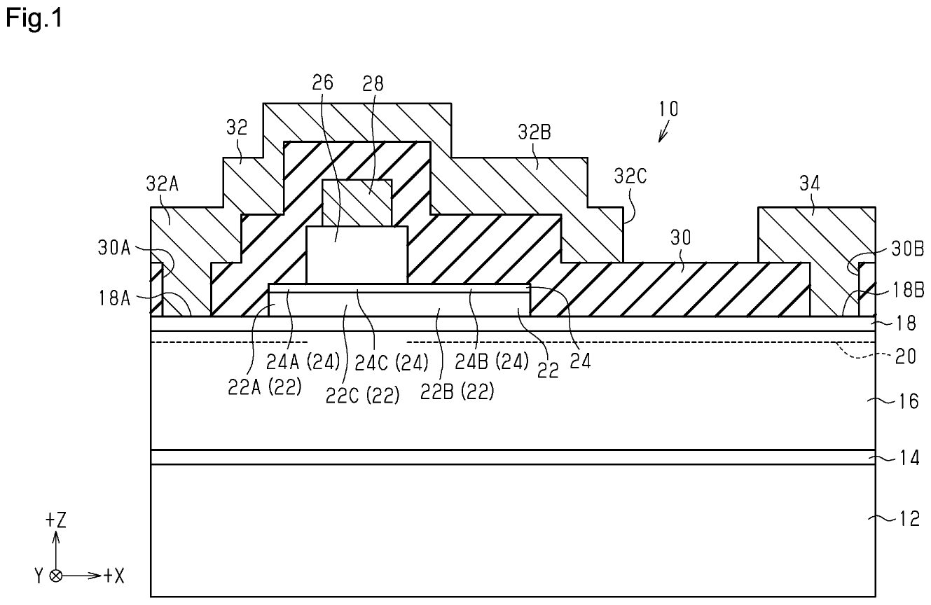

FIG. 1 is a schematic cross-sectional view illustrating an example nitride semiconductor device 10 in accordance with a first embodiment. In this specification, the X-axis, Y-axis, and Z-axis are orthogonal to one another as illustrated in FIG. 1. The term “plan view” as used in this specification is a view of the nitride semiconductor device 10 taken in the Z-axis direction. Further, in FIG. 1 that illustrates the nitride semiconductor device 10, the positive Z-axis direction corresponds to the upward direction, the negative Z-axis direction corresponds to the downward direction, the positive X-axis direction corresponds to the rightward direction, and the negative X-axis direction corresponds to the leftward direction. Unless otherwise indicated, the term “plan view” will refer to a view of the nitride semiconductor device 10 taken from above in the Z-axis direction.

The nitride semiconductor device 10 is a high-electron-mobility transistor (HEMT) that uses a nitride semiconductor and includes a substrate 12, a buffer layer 14 formed on the substrate 12, an electron transfer layer 16 formed on the buffer layer 14, and an electron supplying layer 18 formed on the electron transfer layer 16.

The substrate 12 may be, for example, a silicon substrate. For example, a p-type silicon substrate having an electrical resistivity of 0.001 Ωmm or greater and 0.5 Ωmm or less (or 0.01 Ωmm or greater and 0.1 Ωmm or less) may be used as the substrate 12. A sapphire substrate, a silicon carbide (SiC) substrate, a gallium nitride (GaN) substrate or the like may be used instead of a silicon substrate. The substrate 12 may have a thickness of, for example, 200 μm or greater and 700 μm or less.

The buffer layer 14 may be formed by one or more nitride semiconductor films. For example, the buffer layer 14 may include at least one of an aluminum nitride (AlN) film, an aluminum gallium nitride (AlGaN) film, and an AlGaN composite film having different aluminum (Al) compositions (hereafter, referred to as the graded AlGaN layer). For example, the buffer layer 14 may be formed by a single film of AlN, a single film of AlGaN, a film having an AlGaN/GaN superlattice structure, a film having an AlN/AlGaN superlattice structure, or a film having an AlN/GaN superlattice structure.

In the first embodiment, the buffer layer 14 is multilayered and includes an AlN layer formed as a first buffer layer on the substrate 12 and a graded AlGaN layer formed as a second buffer layer on the AlN layer. In this case, the first buffer layer has a thickness of, for example, 80 nm or greater and 500 nm or less. The second buffer layer may be a graded AlGaN layer formed by three AlGaN layers having Al compositions of 75%, 50%, and 25% in order from the side closer to the first buffer layer. The second buffer layer may have a thickness (total thickness of three AlGaN layers) of, for example, 300 nm or greater and 1 μm or less. The graded AlGaN layer may have any number of AlGaN layers. Further, the AlGaN layers in the graded AlGaN layer may have the same thickness or differ in thickness. To reduce leakage current in the buffer layer 14, part of the buffer layer 14 may include an impurity so that regions other than the outermost part of the buffer layer 14 is semi-insulative. In this case, the impurity may be, for example, carbon (C) or iron (Fe), and the concentration of the impurity may be, for example, 4×10¹⁶ cm⁻³.

The electron transfer layer 16 is formed from a nitride semiconductor and is a GaN layer in the first embodiment. The electron transfer layer 16 may have a thickness of, for example, 0.5 μm or greater and 2 μm or less. To reduce leakage current in the electron transfer layer 16, part of the electron transfer layer 16 may include an impurity so that regions other than the outermost part of the electron transfer layer 16 is semi-insulative. In this case, the impurity may be C, and the concentration of the impurity may be, for example, 4×10¹⁶ cm⁻³.

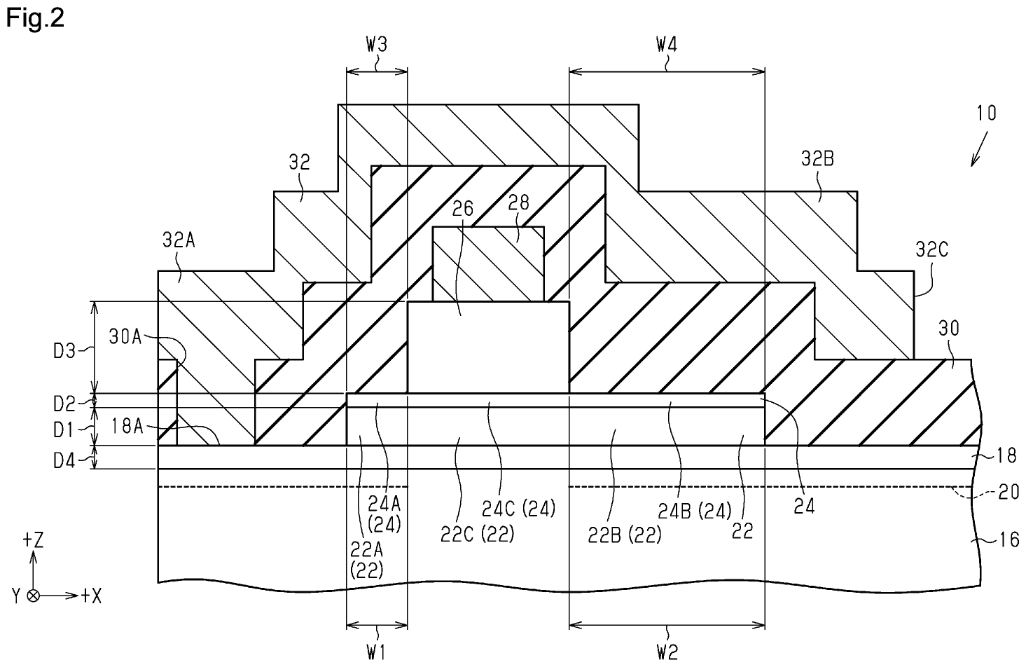

The electron supplying layer 18 is formed from a nitride semiconductor having a larger band gap than the electron transfer layer 16 and is an AlGaN layer in the first embodiment. In a nitride semiconductor, the band gap increases as the Al composition increases. Thus, the electron supplying layer 18, which is an AlGaN layer, has a larger band gap than the electron transfer layer 16, which is a GaN layer. For example, in the first embodiment, the electron supplying layer 18 is formed from AlₓGa₁₋ₓN, where x is preferably, 0<x<0.4, and further preferably, 0.1<x<0.3. The electron supplying layer 18 may have a thickness D4 (refer to FIG. 2) of, for example, 5 nm or greater and 20 nm or less.

The electron transfer layer 16 and the electron supplying layer 18 have different lattice constants in bulk regions and have a lattice-mismatched heterojunction relationship. The spontaneous polarization of the electron transfer layer 16 and the electron supplying layer 18 and the piezoelectric polarization resulting from the compression stress received by the heterojunction of the electron supplying layer 18 causes the energy level of the conduction band of the electron transfer layer 16 to be lower than the Fermi level in the proximity of the heterojunction interface between the electron transfer layer 16 and the electron supplying layer 18. Thus, a two-dimensional electron gas (2DEG) 20 spreads in the electron transfer layer 16 at a position proximate to (e.g., distanced by approximately a few nanometers from interface) the heterojunction interface of the electron transfer layer 16 and the electron supplying layer 18.

The nitride semiconductor device 10 further includes a first step layer 22, which is formed on part of the electron supplying layer 18, and a second step layer 24, which is formed on the first step layer 22. Further, the nitride semiconductor device 10 includes a gate layer 26, which is formed on part of the second step layer 24, and a gate electrode 28, which is formed on the gate layer 26.

The nitride semiconductor device 10 also includes a passivation layer 30, which is formed on the electron supplying layer 18, and a source electrode 32 and drain electrode 34, which extend through the passivation layer 30 and contact the electron supplying layer 18. The passivation layer 30 includes a source contact hole 30A and a drain contact hole 30B that contact part of the upper surface of the electron supplying layer 18 as a source contact 18A and a drain contact 18B. In a cross section taken along a ZX plane of the nitride semiconductor device 10, the source contact 18A, the first step layer 22, and the drain contact 18B are lined in the X-axis direction. Accordingly, the source contact 18A is located in the negative X-axis direction from the first step layer 22 and the drain contact 18B is located in the positive X-axis direction from the first step layer 22. The source electrode 32 and the drain electrode 34 are each joined with the electron supplying layer 18 through the corresponding source contact hole 30A and drain contact hole 30B to be in ohmic contact with the 2DEG 20. Although not illustrated in the drawings, the source electrode 32 is electrically connected to the substrate 12.

The first step layer 22 is formed from a nitride semiconductor and is a GaN layer in the first embodiment. Accordingly, the first step layer 22, which is a GaN layer, has a smaller band gap than the electron supplying layer 18, which is an AlGaN layer. The first step layer 22 serves to diffuse holes. For example, when positive bias is excessively applied to the gate electrode 28, holes are injected into the gate layer 26 from the gate electrode 28. Under such a situation, the first step layer 22 diffuses the holes in the first step layer 22. In other words, the first step layer 22 reduces local hole accumulation at the interface of the gate layer 26 and the electron supplying layer 18 that would occur when the gate layer 26 is directly joined with the electron supplying layer 18. This suppresses band bending of the electron supplying layer 18 (AlGaN layer) and reduces the resulting gate leakage current thereby increasing the gate withstand voltage.

The first step layer 22 may include, for example, at least one of magnesium (Mg) and zinc (Zn) as the acceptor impurity. When the first step layer 22 includes an acceptor impurity, at zero-bias in which voltage is not applied to the gate electrode 28, the acceptor impurity disperses the channel (2DEG 20) of the electron transfer layer 16 in the region underneath the gate electrode 28 and increases the normally-off reliability.

The first step layer 22 is located between the source contact 18A and the drain contact 18B closer to the source contact 18A than the drain contact 18B. The first step layer 22 is not in contact with the source electrode 32 and the drain electrode 34. The source electrode 32 is separated from the first step layer 22 to limit increases in current leakage between the gate and source. The distance between the first step layer 22 and the drain contact 18B in plan view may be set to maintain the withstand voltage between the gate and drain. In one example, the first step layer 22 is separated from the source contact 18A in plan view by, for example, 0.5 μm or greater and separated from the drain contact 18B in plan view by, for example, 3.0 μm or greater.

The first step layer 22 includes a source side extension 22A, a drain side extension 22B, and a base 22C. In the first embodiment, the source side extension 22A and the drain side extension 22B each correspond to “the first extension,” and the base 22C corresponds to “the first base.” Further, the source side extension 22A corresponds to “the first source side extension,” and the drain side extension 22B corresponds to “the first drain side extension.” For example, in the first embodiment, the base 22C is located between the source side extension 22A and the drain side extension 22B in the X-axis direction in FIG. 1. There is no physical boundary between the base 22C and the extensions 22A and 22B. The base 22C is defined by the portion of the first step layer 22 located in the region underneath the gate layer 26 and thus has the same width as the gate layer 26 in the X-axis direction in FIG. 1. Unless otherwise described, the term “width” as referred to in this disclosure is defined as the length in the X-axis direction in FIG. 1.

The source side extension 22A is the part of the first step layer 22 that is adjacent to the base 22C and extends from the boundary with the base 22C in the negative X-axis direction toward the source contact 18A. The drain side extension 22B is the part of the first step layer 22 that is adjacent to the base 22C and extends from the boundary with the base 22C in the positive X-axis direction toward the drain contact 18B. Accordingly, the source side extension 22A and the drain side extension 22B extend outward from the gate layer 26 in plan view.

As illustrated in FIG. 2, the source side extension 22A has a width W1, and the drain side extension 22B has a width W2 that is, for example, greater than the width W1 of the source side extension 22A. The widths W1 and W2 of the extensions 22A and 22B may be set to, for example, improve the hole diffusion effect and increase the gate withstand voltage. Instead or in addition, the width W2 of the drain side extension 22B may be set to, for example, decrease the interface of the electron supplying layer 18 and the passivation layer 30 between the gate electrode 28 and the drain electrode 34 and reduce the effect of electron trapping (or resulting current collapse).

When, for example, the width W1 of the source side extension 22A and the width W2 of the drain side extension 22B are increased, the gate withstand voltage is expected to be increased. This will, however, result in the tradeoffs of (1) the possibility of an increase in the gate-source leakage when the source side extension 22A extends to the vicinity of the source contact 18A, and (2) the effect for expanding a depletion layer from a source field plate (described later) will be reduced when the drain side extension 22B extends over a length longer than a source field plate length. The widths of the extensions 22A and 22B may be set taking the tradeoffs into consideration. For example, the width W1 of the source side extension 22A is 0.1 μm or greater and 0.3 μm or less, and the width W2 of the drain side extension 22B is 0.1 μm or greater and 0.8 μm or less. In the first embodiment, the width W1 of the source side extension 22A is approximately 0.2 μm, and the width W2 of the drain side extension 22B is approximately 0.6 μm. Preferably, the width W1 of the source side extension 22A is less than the gate layer 26, and the width W2 of the drain side extension 22B is greater than the gate layer 26. For example, the width W1 of the source side extension 22A is approximately 0.4 times the width of the gate layer 26, and the width W2 of the drain side extension 22B is approximately 1.2 times the width of the gate layer 26.

The first step layer 22 has a thickness D1 that may be set to, for example, improve the hole diffusion effect and increase the gate withstand voltage. Instead or in addition, the thickness D1 of the first step layer 22 may be set to increase the normally-off reliability. Instead or in addition, the thickness D1 of the first step layer 22 may be set to reduce the ON resistance (Ron) of the nitride semiconductor device 10. Instead or in addition, the thickness D1 of the first step layer 22 may be set to limit 2DEG generation in the first step layer 22.

The thickness D1 of the first step layer 22 may be set to, for example, a given thickness or greater to improve the hole diffusion effect. Further, the thickness D1 of the first step layer 22 may be set to be less than a thickness D3 of the gate layer 26 to decrease the ON resistance while increasing the normally off reliability. The thickness D1 of the first step layer 22 may be set to be a given thickness or less to limit 2DEG generation in the first step layer 22. In one example, the thickness D3 of the gate layer 26 may be 100 nm or greater and 140 nm or less, preferably, 110 nm. The thickness D1 of the first step layer 22 may be, for example, 20 nm or less, preferably, 15 nm or less. The thickness D1 of the first step layer 22 may be, for example, 5 nm or greater to maintain the hole diffusion effect of the first step layer 22.

The second step layer 24 is formed from a nitride semiconductor on the entire upper surface of the first step layer 22 in the first embodiment. The second step layer 24 is an AlGaN layer in the first embodiment. Accordingly, the second step layer 24, which is an AlGaN layer, has a larger band gap than the first step layer 22, which is a GaN layer. Further, the AlGaN forming the second step layer 24 has a lower Al composition than the AlGaN forming the electron supplying layer 18. Accordingly, the second step layer 24 has a smaller bad gap than the electron supplying layer 18.

The Al composition of the second step layer 24 (AlGaN layer) may be set to, for example, increase the etching selection ratio when forming the gate layer 26 through an etching process, which will be described later. Instead or in addition, the Al composition of the second step layer 24 may be set to, for example, limit 2DEG generation in the first step layer 22 (GaN layer). In one example, in the first embodiment, the electron supplying layer 18 is formed from AlₓGa₁₋ₓN (e.g., 0<x<0.4, preferably, 0.1<x<0.3), and the second step layer 24 is formed from Al_{y}Ga_{1-y}N (e.g., 0<y<x, preferably, 0.05<y<x).

In the same manner as the first step layer 22, the second step layer 24 may include, for example, at least one of Mg and Zn as an acceptor impurity. When the second step layer 24 includes an acceptor impurity, at zero-bias state, the acceptor impurity disperses the channel (2DEG 20) of the electron transfer layer 16 in the region underneath the gate electrode 28 and increases the normally-off reliability.

The second step layer 24 includes a source side extension 24A, a drain side extension 24B, and a base 24C. In the first embodiment, the source side extension 24A and the drain side extension 24B each correspond to “the second extension,” and the base 24C corresponds to “the second base.” Further, the source side extension 24A corresponds to “the second source side extension,” and the drain side extension 24B corresponds to “the second drain side extension.” The base 24C is located between the source side extension 24A and the drain side extension 24B in the X-axis direction in FIG. 1. There is no physical boundary between the base 24C and the extensions 24A and 24B. The base 24C is defined by the portion of the second step layer 24 located in the region underneath the gate layer 26 and thus has the same width as the gate layer 26.

The source side extension 24A is the part of the second step layer 24 that is adjacent to the base 24C and extends from the boundary with the base 24C in the negative X-axis direction toward the source contact 18A. The drain side extension 24B is the part of the second step layer 24 that is adjacent to the base 24C and extends from the boundary with the base 24C in the positive X-axis direction toward the drain contact 18B. Accordingly, the source side extension 24A and the drain side extension 24B extend outward from the gate layer 26 in plan view.

The source side extension 24A has a width W3, and the drain side extension 24B has a width W4. In the first embodiment, the width W3 of the source side extension 24A of the second step layer 24 is set to be the same as the width W1 of the source side extension 22A of the first step layer 22. Further, the width W4 of the drain side extension 24B of the second step layer 24 is set to be the same as the width W2 of the drain side extension 22B of the first step layer 22. Thus, in the first embodiment, the source side extension 24A covers the entire upper surface of the source side extension 22A, and the drain side extension 24B covers the entire upper surface of the drain side extension 22B.

As described above, in the first step layer 22, the width W2 of the drain side extension 22B is greater than the width W1 of the source side extension 22A. Thus, in the second step layer 24, the width W4 of the drain side extension 24B is greater than the width W3 of the source side extension 24A. The source side extension 24A of the second step layer 24 covers the entire upper surface of the source side extension 22A of the first step layer 22. Thus, the source side extension 22A is protected over its entire width W1 by the source side extension 24A from processing damages. This keeps the thickness D1 of the source side extension 22A uniform.

In the same manner, the drain side extension 24B of the second step layer 24 covers the entire upper surface of the drain side extension 22B of the first step layer 22. Thus, the drain side extension 22B is protected over its entire width W2 by the drain side extension 24B from processing damages. This keeps the thickness D1 of the drain side extension 22B uniform.

The thickness D1 of the source side extension 22A and the drain side extension 22B is the same as the thickness D1 of the base 22C. Thus, the thickness D1 of the first step layer 22 is uniform in the source side extension 22A, the drain side extension 22B, and the base 22C.

The widths W3 and W4 of the extensions 24A and 24B may be set to protect the first step layer 22 by, for example, using the AlGaN layer corresponding to the second step layer 24 as an etching stopper layer when forming the gate layer 26 in an etching process, which will be described later. Instead or in addition, the widths W3 and W4 of the extensions 24A and 24B may be set to reduce the heterojunction of the first step layer 22 and the second step layer 24 and limit the effect of 2DEG that may occur in the surface of the first step layer 22. For example, after using the AlGaN layer corresponding to the second step layer 24 as the etching stopper layer, the second step layer 24 may be formed so that the widths W3 and W4 of the extensions 24A and 24B are less than the widths W1 and W2 of the extensions 22A and 22B.

The second step layer 24 may have a thickness D2 that is set to, for example, increase the normally-off reliability. Instead or in addition, the thickness D2 of the second step layer 24 may be set to limit 2DEG generation in the first step layer 22. Instead or in addition, the thickness D2 of the second step layer 24 may be set taking into consideration manufacturing variations (e.g., in-plane variations of etching rate).

For example, the thickness D2 of the second step layer 24 may be set to be a given thickness or greater taking into consideration manufacturing variations to sufficiently obtain the functionality for protecting the first step layer 22. Further, the thickness D2 of the second step layer 24 may be set to be less than the thickness D4 of the electron supplying layer 18 to increase the normally-off reliability while limiting 2DEG generation in the first step layer 22. In one example, the thickness D2 of the second step layer 24 may be 2 nm or greater. When the thickness D4 of the electron supplying layer 18 is, for example, 20 nm or less, the thickness D2 of the second step layer 24 may be, for example, 10 nm or less. Alternatively, when the thickness D4 of the electron supplying layer 18 is, for example, 15 nm or less, the thickness D2 of the second step layer 24 may be, for example, 7 nm or less. In this manner, the thickness D2 of the second step layer 24 may be set to ½ or less of the thickness D4 of the electron supplying layer 18. In the first embodiment, the source side extension 24A, the drain side extension 24B, and the base 24C each have the same thickness D2.

The gate layer 26 is formed by a nitride semiconductor layer and is a GaN layer (p-type GaN layer) doped with an acceptor impurity in the first embodiment. Accordingly, the gate layer 26, which is a p-type GaN layer, has a smaller band gap than the second step layer 24, which is an AlGaN layer. The gate layer 26 is formed on part of the second step layer 24. For example, the gate layer 26 is formed on the second step layer 24 having a trapezoidal cross section, a rectangular cross section, or a ridge-shaped cross section. The thickness D3 of the gate layer 26 may be set to, for example, increase the maximum gate rated voltage in the positive direction, that is, increase the gate withstand voltage. In one example, the thickness D3 of the gate layer 26 may be set to 100 nm or greater and 140 nm or less, preferably, 110 nm. The gate layer 26 may have a width (e.g., bottom width) set to, for example, 0.4 μm or greater and 1.0 μm or less, preferably, 0.5 μm.

Accordingly, the acceptor impurity with which the gate layer 26 is doped may include, for example, at least one of Mg, Zn, and C. In the first embodiment, the acceptor impurity is Mg. In this case, the average Mg concentration of the gate layer 26 may be set to, for example, 1×10¹⁹ cm⁻³ or greater and 3×10¹⁹ cm⁻³ or less, preferably, 2×10¹⁹ cm⁻³. The average doping concentration of the acceptor impurity in the gate layer 26 is set to be higher than the average doping concentration of the acceptor impurity (when included) in the first and second step layers 22 and 24. At zero-bias, the gate layer 26 depletes the 2DEG 20 formed in the electron transfer layer 16 in the region underneath the gate layer 26.

The gate electrode 28 is formed on part of upper surface of the gate layer 26 in the first embodiment. The gate electrode 28 and the gate layer 26 form a Schottky junction. The gate electrode 28 is formed by one or more metal layers and is, for example, a titanium nitride (TiN) layer in the first embodiment. Alternatively, the gate electrode 28 may be formed by a first metal layer of Ti and a second metal layer of TiN applied to the first metal layer. The gate electrode 28 may have a thickness of, for example, 50 nm or greater and 300 nm or less.

The passivation layer 30 covers the electron supplying layer 18, the first step layer 22, the second step layer 24, the gate layer 26, and the gate electrode 28. The passivation layer 30 is formed by, for example, a single film that may be any one a silicon nitride (SiN) film, a silicon dioxide (SiO₂) film, a silicon oxynitride (SiON) film, an alumina (Al₂O₃) film, an AlN film, and an aluminum oxynitride (AlON) film or a composite film that is a combination of two or more of these films. For example, the passivation layer 30 is a SiN layer in the first embodiment. The passivation layer 30 directly covers the upper surface of the electron supplying layer 18, the side surfaces of the first step layer 22, the side surfaces and upper surface of the second step layer 24, the side surfaces and upper surface of the gate layer 26, and the side surfaces and upper surface of the gate electrode 28.

The source electrode 32 and the drain electrode 34 are formed by one or more metal layers. The source electrode 32 includes a source electrode portion 32A and a source field plate portion 32B that is continuous with the source electrode portion 32A.

The source electrode portion 32A includes a filler region that fills the source contact hole 30A, a peripheral region formed integrally with the filler region around the source contact hole 30A in plan view, and an upper region located above the gate electrode 28. The source field plate portion 32B is formed integrally with the upper region of the source electrode portion 32A and arranged on the passivation layer 30 so as to cover the first and second step layers 22 and 24 in plan view. The source field plate portion 32B includes an end 32C in the vicinity of the drain electrode 34, and the end 32C is located between the drain electrode 34 and the first and second step layers 22 and 24 in plan view. In the X-axis direction in FIG. 1, the distance from the end of the gate layer 26 to the end 32C of the source field plate portion 32B (length of source field plate portion 32B) is defined as the source field plate length. The source field plate portion 32B expands the depletion layer in the region underneath the source field plate portion 32B and limits magnetic field concentration in the vicinity of the end of the gate electrode 28 in a state of gate-source voltage Vgs=0V (transistor off) when a high source-drain voltage Vds is applied. The width W2 of the drain side extension 22B of the first step layer 22 is set to be less than or equal to the source field plate length to increase the effect of the source field plate portion 32B.

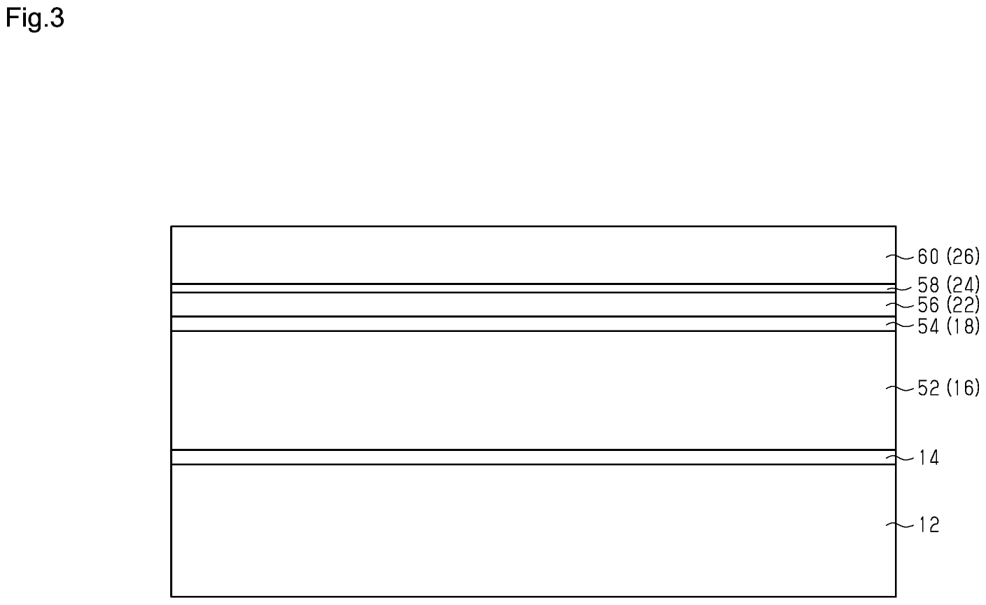

A method for manufacturing the nitride semiconductor device 10 of FIG. 1 will now be described. FIGS. 3 to 9 are schematic cross-sectional views illustrating example manufacturing processes of the nitride semiconductor device 10. In FIGS. 3 to 9, to aid understanding, members including or corresponding to the final elements of the nitride semiconductor device 10 are indicated by the reference characters used in FIG. 1 and illustrated in parenthesis.

The method for manufacturing the nitride semiconductor device 10 includes forming a first nitride semiconductor layer 52 that acts as the electron transfer layer 16, forming a second nitride semiconductor layer 54 that acts as the electron supplying layer 18 on the first nitride semiconductor layer 52, forming a third nitride semiconductor layer 56 on the second nitride semiconductor layer 54, forming a fourth nitride semiconductor layer 58 on the third nitride semiconductor layer 56, and forming a fifth nitride semiconductor layer 60 that includes an acceptor impurity on the fourth nitride semiconductor layer 58.

As illustrated in FIG. 3, in the first embodiment, the buffer layer 14, the first nitride semiconductor layer 52, the second nitride semiconductor layer 54, the third nitride semiconductor layer 56, the fourth nitride semiconductor layer 58, and the fifth nitride semiconductor layer 60 are formed in order through epitaxial growth on the substrate 12, which is, for example, a Si substrate. The epitaxial growth process may be, for example, a metal organic chemical vapor deposition (MOCVD) process.

Although not illustrated in detail, in the first embodiment, for example, the buffer layer 14 includes multiple layers in which an AlN layer (first buffer layer) is formed on the substrate 12 and then a graded AlGaN layer (second buffer layer) is formed on the AlN layer. The graded AlGaN layer is formed by stacking, for example, three AlGaN layers of which the Al compositions are 75%, 50%, and 25% in order from the side closer to the AlN layer.

A GaN layer that acts as the first nitride semiconductor layer 52 is formed on the buffer layer 14, and an AlGaN layer that acts as the second nitride semiconductor layer 54 is formed on the first nitride semiconductor layer 52. Accordingly, the second nitride semiconductor layer 54 has a larger bad gap than the first nitride semiconductor layer 52. The first nitride semiconductor layer 52 corresponds to the electron transfer layer 16 of FIG. 1, and the second nitride semiconductor layer 54 corresponds to the electron supplying layer 18 of FIG. 1. Then, a GaN layer that acts as the third nitride semiconductor layer 56 is formed on the second nitride semiconductor layer 54, and an AlGaN layer that acts as the fourth nitride semiconductor layer 58 is formed on the third nitride semiconductor layer 56. Accordingly, the third nitride semiconductor layer 56 has a smaller band gap than the second nitride semiconductor layer 54, and the fourth nitride semiconductor layer 58 has a larger band gap than the third nitride semiconductor layer 56. Then, a p-type GaN layer acting as the fifth nitride semiconductor layer 60 is formed on the fourth nitride semiconductor layer 58. Accordingly, the fifth nitride semiconductor layer 60 has a smaller band gap than the fourth nitride semiconductor layer 58.

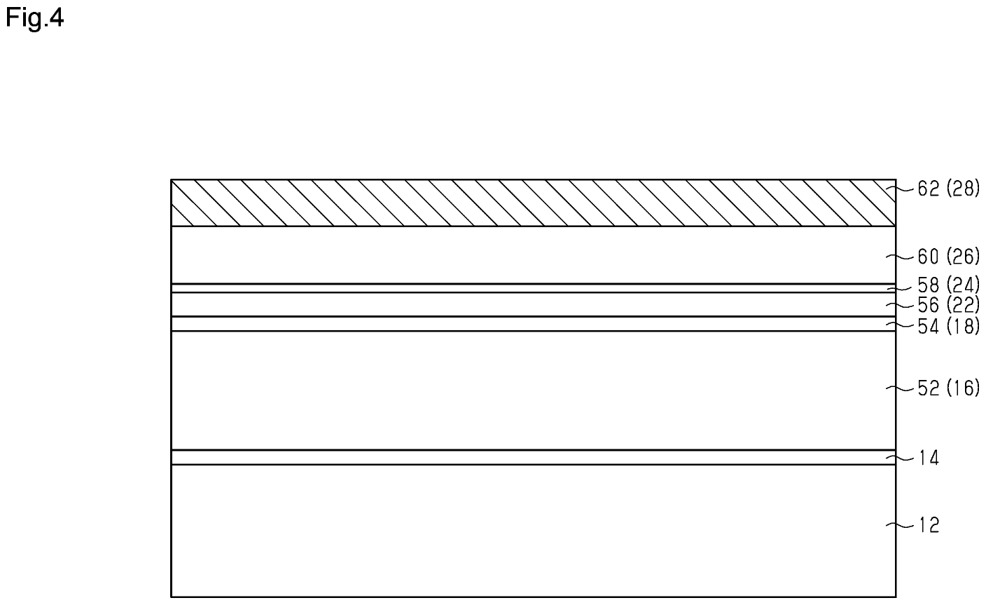

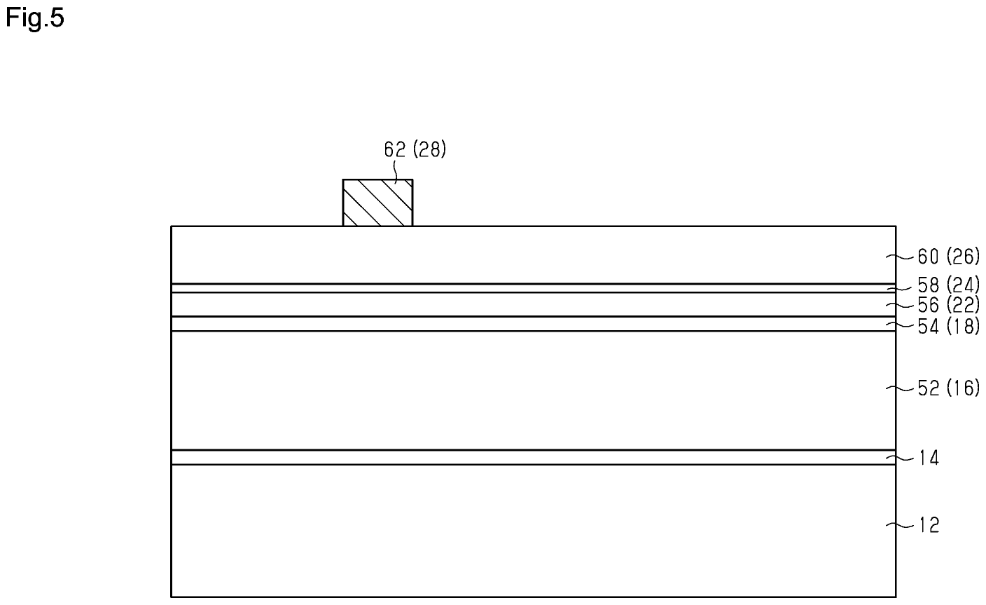

As illustrated in FIGS. 4 and 5, the method for manufacturing the nitride semiconductor device 10 includes forming the gate electrode 28 on the fifth nitride semiconductor layer 60. First, as illustrated in FIG. 4, in the manufacturing step following FIG. 3, a metal layer 62 is formed on the fifth nitride semiconductor layer 60. In the first embodiment, for example, a sputtering process is performed to form a TiN layer that acts as the metal layer 62.

Then, as illustrated in FIG. 5, in the manufacturing step following FIG. 4, the metal layer 62 is selectively etched to form the gate electrode 28. In the first embodiment, for example, a mask (not illustrated) is formed on the upper surface of the metal layer 62 illustrated in FIG. 4 at a position corresponding to where the gate electrode 28 is formed. The mask is used to perform etching (e.g., dry etching) and pattern the metal layer 62 to form the gate electrode 28. Then, the mask is removed with a delamination liquid.

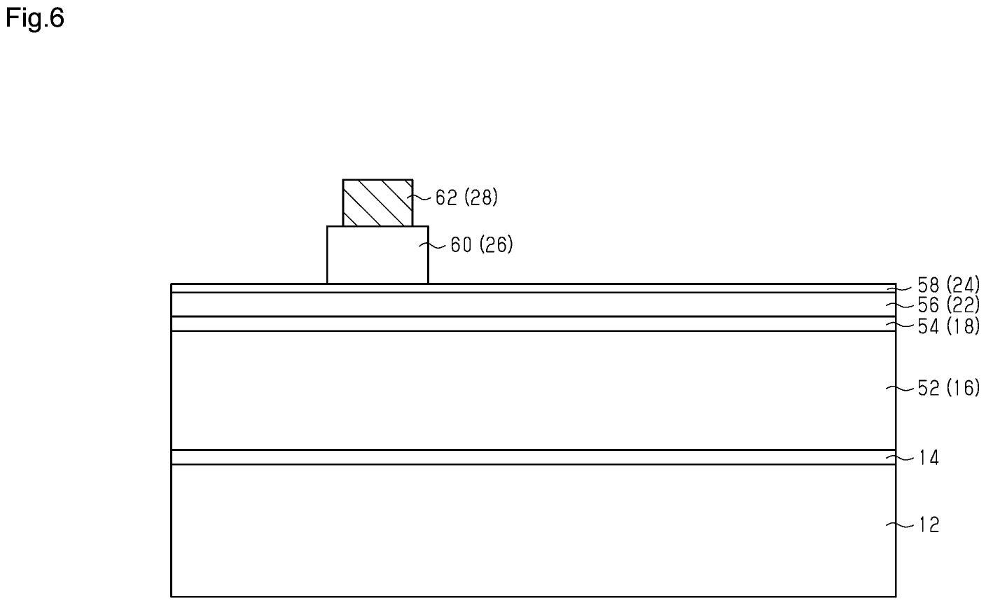

As illustrated in FIG. 6, in the manufacturing step following FIG. 5, the method for manufacturing the nitride semiconductor device 10 includes selectively etching the fifth nitride semiconductor layer 60 to form the gate layer 26. The gate layer 26 is formed so that the gate electrode 28 is formed on the gate layer 26. In the first embodiment, for example, a mask (not illustrated) that entirely covers the gate electrode 28 is formed on the upper surface of the fifth nitride semiconductor layer 60 illustrated in FIG. 5 at a position corresponding to where the gate layer 26 is formed. The mask is used to perform etching (e.g., dry etching) and pattern the fifth nitride semiconductor layer 60 to form the gate layer 26. The gate layer 26 may have a trapezoidal cross section, a rectangular cross section, or a ridge-shaped cross section. Then, the mask is removed with a delamination liquid.

The etching step of the fifth nitride semiconductor layer 60 may include etching steps of different etching conditions, for example, a first etching step and a second etching step. In this case, the first etching step starts the etching of the fifth nitride semiconductor layer 60, and the first etching step shifts to the second etching step before the upper surface of the fourth nitride semiconductor layer 58 used as an etching stopper layer becomes exposed. The etching of the fifth nitride semiconductor layer 60 ends in the second etching step.

In this method, the etching condition of the first etching step is selected to shorten the total time for etching the fifth nitride semiconductor layer 60, and the etching condition of the second etching step is selected to obtain a higher selective etching ratio (in this case, selective etching ratio of fifth nitride semiconductor layer 60 to fourth nitride semiconductor layer 58) than the first etching step. For example, in the second etching step, the etching condition is selected to obtain a selective etching ratio of approximately 10 or greater.

In one example, the first etching step may be a dry etching step using a gas mixture, in which a diluent gas is added to a chlorine gas (e.g., chlorine (Cl₂) gas or silicon tetrachloride (SiCl₄) gas) as a first etching gas. In this case, the diluent gas may be, for example, a gas including nitrogen (e.g., N₂ gas) or argon (Ar) gas. The second etching step may be a dry etching step using a gas mixture, in which a selective ratio adjustment gas is added to a chlorine gas (e.g., Cl₂ gas or SiCl₄ gas), as a second etching gas. In this case, the selective ratio adjustment gas may be, for example, a gas including fluorine (e.g., carbon tetrafluoride (CF₄) gas) or a gas including oxygen (e.g., O₂ gas). Alternatively, the second etching gas may be a gas mixture, in which a diluent gas and a selective ratio adjustment gas are both added to a chlorine gas. In the example described here, the first and second etching step are performed. More etching steps may be formed as long as the final etching step of the fifth nitride semiconductor layer 60 is performed in the same manner as the second etching step.

When performing the second etching step as the final etching step of the fifth nitride semiconductor layer 60, the fourth nitride semiconductor layer 58 will serve as a good etching stopper layer. As described with reference to FIG. 1, the Al composition of AlGaN in the second step layer 24 is lower than the Al composition of AlGaN in the electron supplying layer 18 to increase the selective etching ratio and limit 2DEG generation in the first step layer 22. In addition, the second step layer 24 is thinner than the gate layer 26. With such a structure, the second etching step may be performed to obtain the desired selective etching ratio. The second etching step controls the selective etching ratio to avoid undesirable etching of the fourth nitride semiconductor layer 58 (second step layer 24) in the final etching step of the fifth nitride semiconductor layer 60. As a result, the fourth nitride semiconductor layer 58 (second step layer 24) serves to effectively protect the third nitride semiconductor layer 56 (first step layer 22).

Dry etching may be performed by using, for example, an inductively coupled plasma (ICP) etching device. Although not illustrated in the drawings, the ICP etching device includes a plasma generating power supply that supplies electric power for generating plasma from an etching gas and a bias power supply that supplies electric power for drawing ions from the plasma toward an etching subject (e.g., fifth nitride semiconductor layer 60 in FIG. 6) on a stage. In such an ICP etching device, the ion drawing electric power of the bias power supply may be controlled to obtain the desired selective etching ratio. For example, the ion drawing electric power may be set to less than 5 watts (W) in the second etching step to adjust the selective etching ratio of the fifth nitride semiconductor layer 60 to the fourth nitride semiconductor layer 58 to approximately 10 or greater.

When the fourth nitride semiconductor layer 58 is formed by an AlGaN layer including Zn, plasma emission caused by the Zn occurs when the etching of the fifth nitride semiconductor layer 60 reaches the fourth nitride semiconductor layer 58. The plasma emission may be captured to control and stop etching of the fifth nitride semiconductor layer 60 with further accuracy.

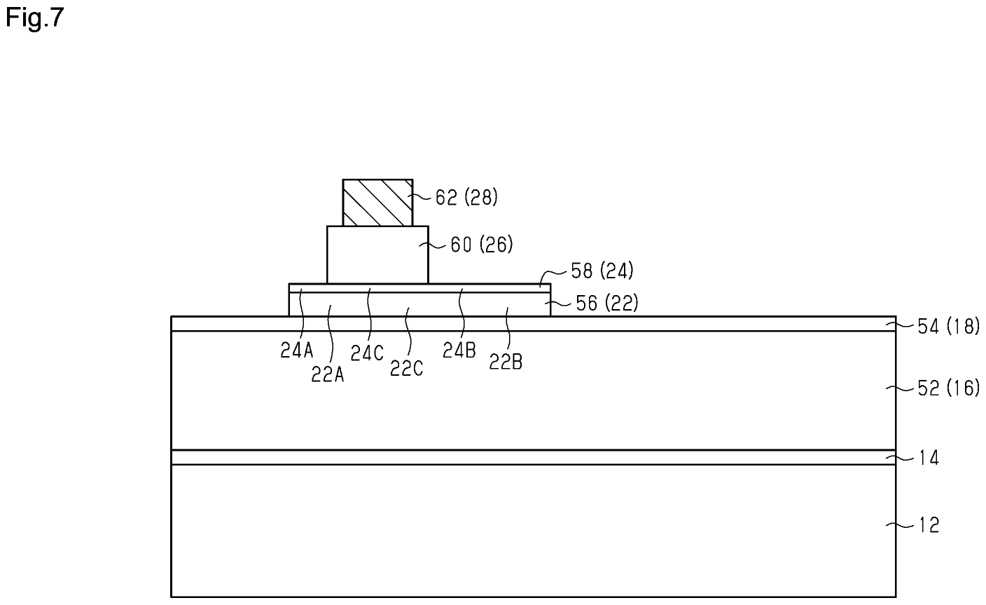

As illustrated in FIG. 7, in the manufacturing step following FIG. 6, the method for manufacturing the nitride semiconductor device 10 includes forming the first step layer 22, which is located on part of the electron supplying layer 18, and forming the second step layer 24, which is located on the first step layer 22. Here, after selectively etching the fourth nitride semiconductor layer 58 and forming the second step layer 24, the third nitride semiconductor layer 56 is selectively etched to form the first step layer 22. In the etching process illustrated in FIG. 7, the method for manufacturing the nitride semiconductor device 10 includes forming the extensions 22A and 22B that extend outward from the gate layer 26 in plan view on the first step layer 22,

In the first embodiment, for example, a mask (not illustrated) that entirely covers both of the gate layer 26 and the gate electrode 28 is formed on the upper surface of the fourth nitride semiconductor layer 58 illustrated in FIG. 6 at a position corresponding to where the first and second step layers 22 and 24 are formed. The mask is used to perform etching (e.g., dry etching) and pattern the fourth nitride semiconductor layer 58 and the third nitride semiconductor layer 56 in order to form the second step layer 24 and the first step layer 22. In the first embodiment, the base 24C and the source side extension 24A and drain side extension 24B, which are located at opposite sides of the base 24C, are formed in the second step layer 24. Further, the base 22C and the source side extension 22A and drain side extension 22B, which are located at opposite sides of the base 22C, are formed in the first step layer 22. The base 24C of the second step layer 24 is located on the base 22C of the first step layer 22. The extensions 24A and 24B of the second step layer 24 are respectively located on the extensions 22A and 22B of the first step layer 22. Then, the mask is removed with a delamination liquid.

The etching step of the fourth nitride semiconductor layer 58 and the third nitride semiconductor layer 56 may include a plurality of etching steps, for example, first and second etching steps in the same manner as when etching the fifth nitride semiconductor layer 60 as described above. In this case, the first etching step starts the etching of the fourth nitride semiconductor layer 58, and the first etching step shifts to the second etching step before the upper surface of the second nitride semiconductor layer 54 (electron supplying layer 18) becomes exposed. The etching of the third nitride semiconductor layer 56 ends in the second etching step.

In this method, in the same manner as the etching step of the fifth nitride semiconductor layer 60, the etching condition of the first etching step is selected to shorten the total time for etching the fourth nitride semiconductor layer 58 and the third nitride semiconductor layer 56, and the etching condition of the second etching step is selected to obtain a higher selective etching ratio (in this case, selective etching ratio of third nitride semiconductor layer 56 to second nitride semiconductor layer 54) than the first etching step. For example, in the second etching step, the etching condition is selected to obtain a selective etching ratio of approximately 10 or greater. Alternatively, more etching steps may be performed as long as the etching step of the third nitride semiconductor layer 56 includes the second etching step such as that described above. Such a method avoids undesirable etching of the electron supplying layer 18 in the etching step of the third nitride semiconductor layer 56.

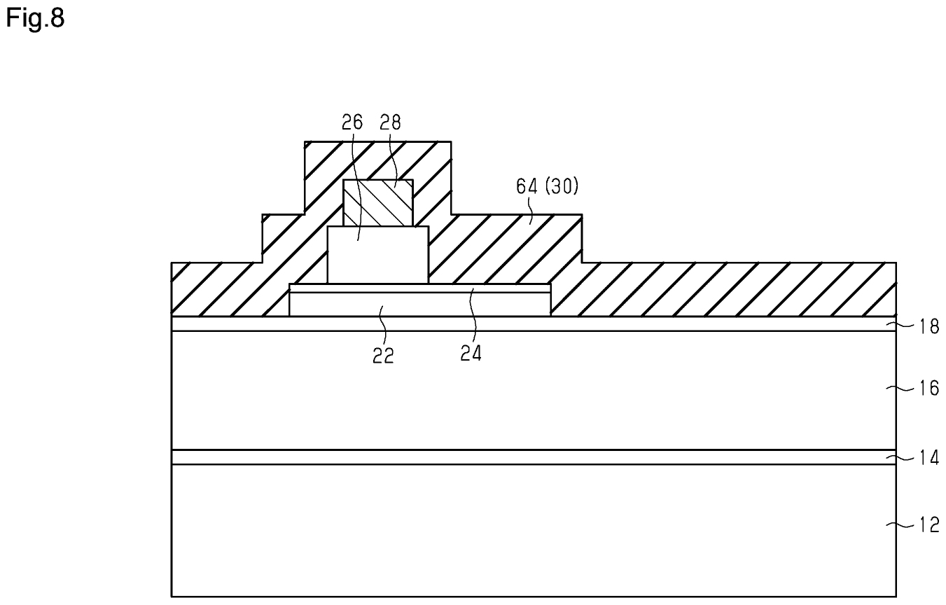

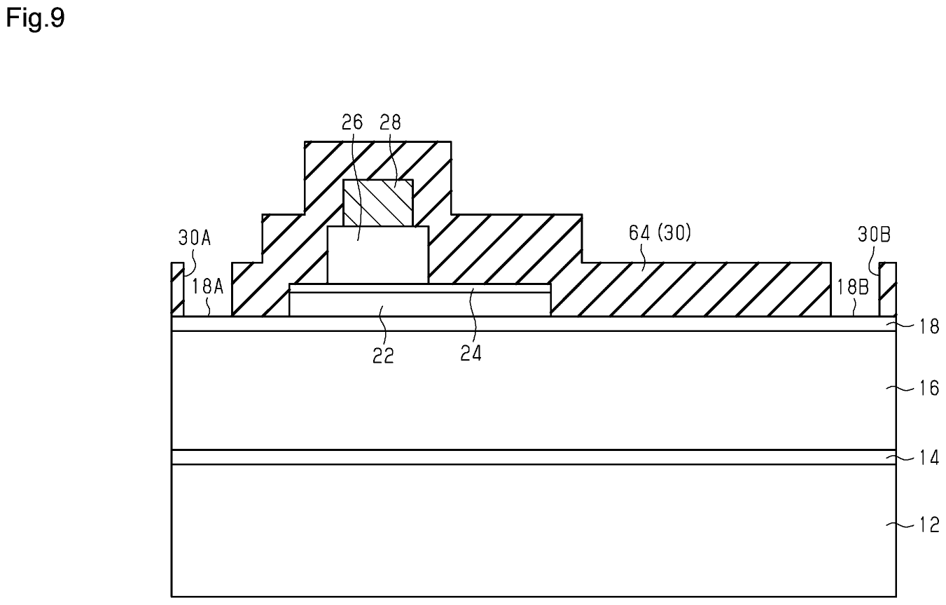

Then, after the steps illustrated in FIGS. 8 and 9, the method for manufacturing the nitride semiconductor device 10 includes forming the source electrode 32 (refer to FIG. 1) and the drain electrode 34 (refer to FIG. 1) that are in contact with the electron supplying layer 18. First, as illustrated in FIG. 8, in the manufacturing step following FIG. 7, a dielectric layer 64 covering the first step layer 22, the second step layer 24, the gate layer 26, and the gate electrode 28 is formed on the electron supplying layer 18. In the first embodiment, for example, a SiN layer is formed as the dielectric layer 64. The dielectric layer 64 corresponds to the passivation layer 30 of FIG. 1.

Then, as illustrated in FIG. 9, in the manufacturing step following FIG. 8, the source electrode 32 (refer to FIG. 1) and the drain electrode 34 (refer to FIG. 1) are formed extending through the dielectric layer 64 (passivation layer 30) and contacting the electron supplying layer 18. In the first embodiment, for example, the source contact hole 30A and the drain contact hole 30B are formed in the dielectric layer 64 exposing parts of the upper surface of the electron supplying layer 18 as the source contact 18A and the drain contact 18B, respectively. Then, the contact holes 30A and 30B are filled with a metal layer (one or more metal layers) that covers the passivation layer 30, and photolithography or etching is performed to pattern the metal layer and form the source electrode 32 and the drain electrode 34 illustrated in FIG. 1. This obtains the nitride semiconductor device 10 of FIG. 1.

The operation of the nitride semiconductor device 10 will now be described.

As described above, the gate layer 26, which is formed from p-type GaN, is located below the gate electrode 28. The acceptor impurity included in the gate layer 26 raises the energy level of the electron transfer layer 16 and the electron supplying layer 18. Thus, the energy level of the conduction band of the electron transfer layer 16 is substantially the same as or greater than the Fermi level in the proximity of the heterojunction interface between the electron transfer layer 16 and the electron supplying layer 18 in the region underneath the gate layer 26. Accordingly, at zero-bias, the 2DEG 20 is not formed in the electron transfer layer 16 in the region underneath the gate layer 26, and the 2DEG 20 is formed in the electron transfer layer 16 outside the region underneath the gate layer 26. This obtains the normally-off characteristic. When a proper ON voltage is applied to the gate electrode 28, a channel (2DEG 20) is induced in the electron transfer layer 16 in the region underneath the gate electrode 28 to electrically connect the source and drain.

When positive bias is excessively applied to the gate electrode 28, holes are injected into the gate layer 26 from the gate electrode 28. Under such a situation, the first step layer 22 diffuses the holes in the first step layer 22 and reduces the accumulation of holes in the interface of the first step layer 22 and the electron supplying layer 18. This suppresses band bending of the electron supplying layer 18 (AlGaN layer) and reduces the resulting gate leakage current thereby increasing the gate withstand voltage.

In a transistor-off state, when high voltage is applied between the drain and source, electrons are trapped by defective crystals and layer interfaces inside the transistor, for example, in the electron transfer layer or in the surface of the electron supplying layer. Such electrons hinder the generation of two-dimensional electron gas. In this case, it is known that the ON resistance will increase when the transistor is switched on next. This effect is referred to as a current collapse.

In the nitride semiconductor device 10, the first and second step layers 22 and 24 arranged below the gate layer 26 are wider than the gate layer 26. Thus, the upper surface of the electron supplying layer 18 in the vicinity of the gate layer 26 is not exposed to etching gas. Further, the extensions 24A and 24B of the second step layer 24 are located on the extensions 22A and 22B of the first step layer 22. Thus, the upper surface of the first step layer 22 is not exposed to etching gas when the gate layer 26 is etched. More specifically, the fourth nitride semiconductor layer 58 of FIG. 6 is used as an etching stopper layer so that the first step layer 22 is protected by the second step layer 24. Thus, the physical distance between the etching layer and the 2DEG 20 in the vicinity of the gate layer 26 is greater than when there is no second step layer 24. Electron trapping occurs rather easily in the etching surface. The separation of the etching surface from the 2DEG 20 reduces the effect that the electrons trapped in the etching surface has on the 2DEG 20. This, in turn, suppresses current collapse.

The first embodiment has the advantages described below.

(1-1) The first step layer 22 includes the source side extension 22A and the drain side extension 22B that extend outward from the gate layer 26 in plan view. The extensions 22A and 22B serve to diffuse holes. For example, even under a situation in which positive bias is excessively applied to the gate electrode 28 and holes are injected into the gate layer 26 from the gate electrode 28, the holes are diffused in the source side extension 22A and the drain side extension 22B of the first step layer 22. In other words, the two extensions 22A and 22B of the first step layer 22 reduce local hole accumulation at the interface where the gate layer 26 and the electron supplying layer 18 are directly joined. This suppresses band bending of the electron supplying layer 18 (AlGaN layer) and reduces the resulting gate leakage current thereby increasing the gate withstand voltage.

(1-2) The second step layer 24 includes the source side extension 24A, which is formed on the source side extension 22A of the first step layer 22, and the drain side extension 24B, which is formed on the drain side extension 22B of the first step layer 22. The extensions 24A and 24B of the second step layer 24 are formed as parts of the fourth nitride semiconductor layer 58 (refer to FIG. 6) used as an etching stopper layer when the gate layer 26 is forming in an etching process. Accordingly, the extensions 24A and 24B of the second step layer 24 function to protect the extensions 22A and 22B of the first step layer 22 from the etching process when the gate layer 26 is formed. As a result, the thicknesses D1 and D2 of the extensions 22A and 22B of the first step layer 22, which extend outward from the gate layer 26, remain the same as the thickness of the base 22C, which is located under the gate layer 26. This increases the hole diffusion effect in the extensions 22A and 22B of the first step layer 22.

(1-3) The extensions 22A and 22B of the first step layer 22 are protected by the extensions 24A and 24B of the second step layer 24 from the etching process. Thus, the upper surface of the first step layer 22 is not exposed to etching gas. This increases the physical distance between the 2DEG 20 and the etching surface in the vicinity of the gate layer 26, as compared with when there is no second step layer 24. Electron trapping occurs rather easily in the etching surface. The separation of the etching surface from the 2DEG 20 reduces the effect that the electrons trapped in the etching surface has on the 2DEG 20. This, in turn, suppresses current collapse.

(1-4) The width W3 of the source side extension 24A of the second step layer 24 is equal to the width W1 of the source side extension 22A of the first step layer 22. Further, the width W4 of the drain side extension 24B of the second step layer 24 is equal to the width W2 of the drain side extension 22B of the first step layer 22. Accordingly, the extensions 24A and 24B of the second step layer 24 protect the entire surfaces of the extensions 22A and 22B of the first step layer 22. This maintains the thickness D1 of the first step layer 22 in a satisfactory manner and increases the hole diffusion effect in the extensions 22A and 22B.

(1-5) The thickness D2 of the second step layer 24 is less than the thickness D4 of the electron supplying layer 18. The second step layer 24 also has a smaller band gap than the electron supplying layer 18. When 2DEG is generated in the first step layer 22 at the interface of the first step layer 22 and the second step layer 24, a current path leading to the 2DEG 20 of the electron transfer layer 16 may form and cause current leakage. Further, when 2DEG is generated in the first step layer 22, the depletion of the 2DEG 20 in the electron transfer layer 16 may be hindered. Such situations are taken into consideration when setting the thickness D4 and band gap of the electron supplying layer 18 in relation with the thickness D2 and band gap of the second step layer 24. This limits the generation of 2DEG in the first step layer 22 and increases the normally-off reliability.

(1-6) At least one of the first and second step layers 22 and 24 includes an acceptor impurity. This increases the effect for depleting the 2DEG 20 in the region of the electron transfer layer 16 underneath the gate layer 26 at zero bias and increases the normally-off reliability.

(1-7) The thickness D1 of the first step layer 22 is less than the thickness D3 of the gate layer 26. This decreases the ON resistance while increasing the normally-off reliability.

(1-8) In the etching process of the gate layer 26 (FIG. 7), a plurality of etching steps may be performed. For example, in a first etching step, etching of the fifth nitride semiconductor layer 60 is started. The first etching step shifts to a second shifting step before the upper surface of the fourth nitride semiconductor layer 58 becomes exposed. Then, the etching of the fifth nitride semiconductor layer 60, which uses the fourth nitride semiconductor layer 58 as an etching stopper layer, ends in the second etching step. In the second etching step, the selective etching ratio of the fifth nitride semiconductor layer 60 to the fourth nitride semiconductor layer 58 is set to be higher than the first etching step. This method forms the gate layer 26 by etching the fifth nitride semiconductor layer 60 while using the fourth nitride semiconductor layer 58 as an etching stopper layer in a satisfactory manner. Thus, the thickness of the fourth nitride semiconductor layer 58 corresponding to the thickness D2 of the second step layer 24 and the thickness of the third nitride semiconductor layer 56 corresponding to the thickness D1 of the first step layer 22 are maintained in a satisfactory manner.

(1-9) In the etching process of the first and second step layers 22 and 24 (FIG. 7), a plurality of etching steps may be performed. For example, in a first etching step, etching of the fourth nitride semiconductor layer 58 is started. The first etching step shifts to a second shifting step before the upper surface of the second nitride semiconductor layer 54 (electron supplying layer 18) becomes exposed. Then, the etching of the third nitride semiconductor layer 56, which uses the second nitride semiconductor layer 54 (electron supplying layer 18) as an etching stopper layer, ends in the second etching step. In the second etching step, the selective etching ratio of the third nitride semiconductor layer 56 to the second nitride semiconductor layer 54 is set to be higher than the first etching step. This method forms the first step layer 22 by etching the third nitride semiconductor layer 56 while using the second nitride semiconductor layer 54 as an etching stopper layer in a satisfactory manner. Thus, the thickness of the second nitride semiconductor layer 54 corresponding to the thickness D4 of the electron supplying layer 18 and the thickness of the first nitride semiconductor layer 52 corresponding to the thickness of the electron transfer layer 16 are maintained in a satisfactory manner.

### Second Embodiment

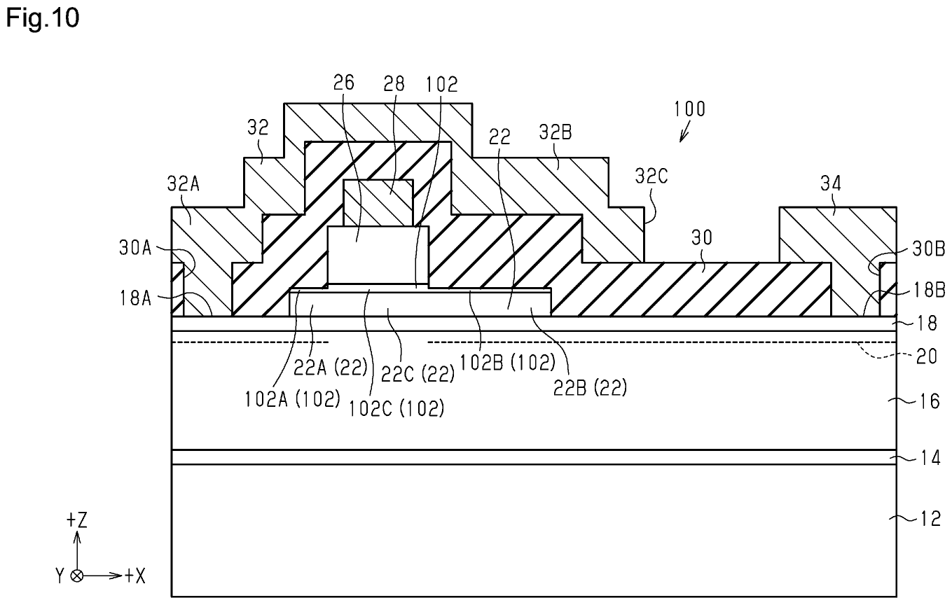

FIG. 10 is a schematic cross-sectional view illustrating an example nitride semiconductor device 100 in accordance with a second embodiment. In FIG. 10, same reference characters are given to those elements that are the same as the corresponding elements in the nitride semiconductor device 10 of the first embodiment. Elements that are the same as the corresponding elements in the first embodiment will not be described in detail. The description will focus on differences from the first embodiment.

The nitride semiconductor device 100 includes a second step layer 102 instead of the second step layer 24 of the first embodiment (refer to FIG. 1). The second step layer 102 is an AlGaN layer in the second embodiment.

The second step layer 102 of the second embodiment includes a source side extension 102A, a drain side extension 102B, and a base 102C. The source side extension 102A corresponds to the source side extension 24A of the second step layer 24 of the first embodiment, and the drain side extension 102B corresponds to the drain side extension 24B of the second step layer 24 of the first embodiment. The base 102C corresponds to the base 24C of the second step layer 24 of the first embodiment. In the second step layer 102, the source side extension 102A and the drain side extension 102B each have a smaller thickness than the base 102C, for example, a thickness that is one-half of the base 102C. In other words, the thickness of the second step layer 102 is one-half the thickness of the extensions 24A and 24B of the second step layer 24 of the first embodiment. Except in that the extensions 102A and 102B are thinner than the base 102C, the second step layer 102 of the second embodiment has the same structure as the second step layer 24 of the first embodiment.

After the gate layer 26 of FIG. 6 is formed, the second step layer 102 (extensions 102A and 102B and base 102C) of the second embodiment may be formed by, for example, etching the portion of the fourth nitride semiconductor layer 58 that does not correspond to the base 102C and reducing the thickness of this portion. Subsequent to the formation of the second step layer 102, etching is performed in the same manner as illustrated in FIG. 7 to form the first step layer 22.

The second embodiment has the advantage described below in addition to the advantages of the first embodiment.

(2-1) The extensions 102A and 102B are thinner than the base 102C and limit the generation of 2DEG in the first step layer 22.

### Third Embodiment

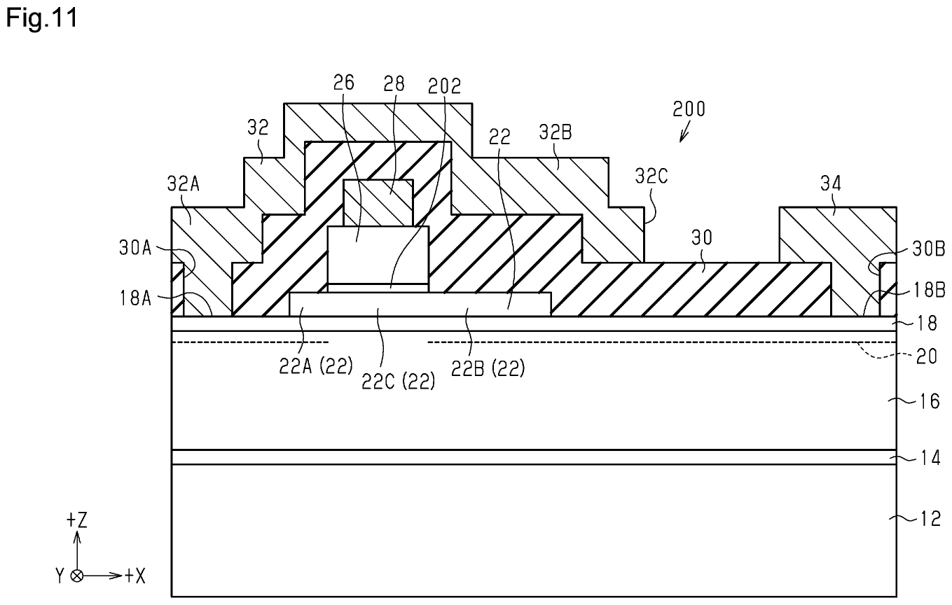

FIG. 11 is a schematic cross-sectional view illustrating an example nitride semiconductor device 200 in accordance with a third embodiment. In FIG. 11, same reference characters are given to those elements that are the same as the corresponding elements in the nitride semiconductor device 10 of the first embodiment. Elements that are the same as the corresponding elements in the first embodiment will not be described in detail. The description will focus on differences from the first embodiment.

The nitride semiconductor device 200 includes a second step layer 202 instead of the second step layer 24 of the first embodiment (refer to FIG. 1). The second step layer 202 is an AlGaN layer in the third embodiment.

The second step layer 202 is formed on the base 22C of the first step layer 22 only in the region underneath the gate layer 26. In other words, the second step layer 202 of the second embodiment is obtained by omitting the extensions 24A and 24B from the second step layer 24 of the third embodiment. Except in that there are no extensions, the second step layer 202 of the third embodiment has the same structure as the second step layer 24 of the first embodiment.

After the gate layer 26 of FIG. 6 is formed, for example, the portion of the fourth nitride semiconductor layer 58 that does not correspond to the second step layer 202 may be etched and removed. Subsequent to the formation of the second step layer 202, etching is performed in the same manner as illustrated in FIG. 7 to form the first step layer 22.

The third embodiment has the advantages described below in addition to the advantages of the first embodiment.

(3-1) The second step layer 202, which is an AlGaN layer, is formed on the base 22C of the first step layer 22 only in the region underneath the gate layer 26. This limits the generation of 2DEG in the extensions 22A and 22B of the first step layer 22. This also reduces the effect of electron trapping (or resulting current collapse) that occurs in the interface of the first step layer 22 (GaN layer) and the second step layer 202 (AlGaN layer).

(3-2) After the gate layer 26 of FIG. 6 is formed, the portion of the fourth nitride semiconductor layer 58 that does not correspond to the second step layer 202 may be etched and removed to form the second step layer 202. In other words, in the same manner as the first embodiment, when the gate layer 26 is formed in the etching process, the fourth nitride semiconductor layer 58 on the first step layer 22 is used as an etching stopper layer. Thus, in the same manner as the first embodiment, the first step layer 22 is protected from damages resulting from the etching process.

### Fourth Embodiment

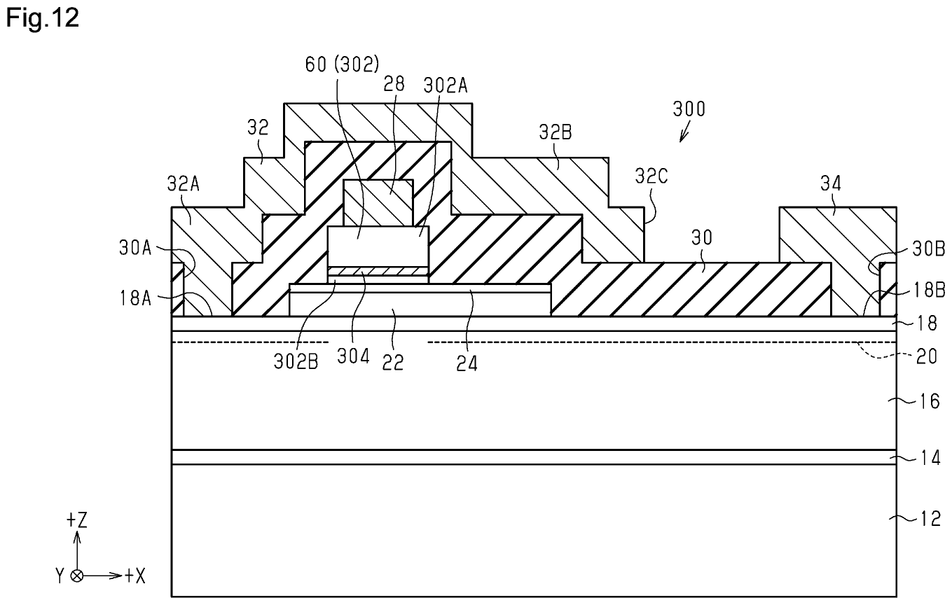

FIG. 12 is a schematic cross-sectional view illustrating an example nitride semiconductor device 300 in accordance with a fourth embodiment. In FIG. 12, same reference characters are given to those elements that are the same as the corresponding elements in the nitride semiconductor device 10 of the first embodiment. Elements that are the same as the corresponding elements in the first embodiment will not be described in detail. The description will focus on differences from the first embodiment.

The nitride semiconductor device 300 includes a gate layer 302 instead of the gate layer 26 (refer to FIG. 1) of the first embodiment. The gate layer 302 is a p-type GaN layer in the fourth embodiment.

The gate layer 302 is divided into two divisional layers, namely, an upper layer 302A and a lower layer 302B, that are separated from each other in the direction in which the gate layer 302 is stacked on the second step layer 24. The nitride semiconductor device 300 further includes a nitride semiconductor layer 304 that is in contact with the upper layer 302A and the lower layer 302B and located between the upper layer 302A and the lower layer 302B. Each of the upper layer 302A and the lower layer 302B is, for example, a p-type GaN layer, and the nitride semiconductor layer 304 is, for example, an AlGaN layer. Accordingly, the nitride semiconductor layer 304, which is an AlGaN layer, has a larger band gap than the upper layer 302A and the lower layer 302B, which are p-type GaN layers.

In the fourth embodiment, the upper layer 302A and the lower layer 302B of the gate layer 302 are formed using the fifth nitride semiconductor layer 60 (p-type GaN layer) as a material layer in the same manner as when forming the gate layer 26 as illustrated in FIG. 6. The nitride semiconductor layer 304 may be formed, for example, by using an AlGaN layer as a material layer in the same manner as the fourth nitride semiconductor layer 58 (AlGaN layer) illustrated in FIG. 6.

In the fourth embodiment, in the same manner as when etching the fifth nitride semiconductor layer 60 using the fourth nitride semiconductor layer 58 of FIG. 6 as an etching stopper layer, the AlGaN layer that is the material layer of the nitride semiconductor layer 304 is used as an etching stopper layer. The step of forming the gate layer 302 of FIG. 12 will now be described with reference to FIG. 6. First, the fifth nitride semiconductor layer 60 (portion corresponding to upper layer 302A) of FIG. 6 is etched using the material layer (AlGaN layer) of the nitride semiconductor layer 304 as an etching stopper layer to form the upper layer 302A. Then, the nitride semiconductor layer 304 is formed. In the same manner as FIG. 6, the fifth nitride semiconductor layer 60 (portion corresponding to lower layer 302B) is then etched using the fourth nitride semiconductor layer 58 as an etching stopper layer to form the lower layer 302B.

The etching process used to form the gate layer 26 of the first embodiment (FIG. 6) may be applied as the etching process used to form the gate layer 302 of the fourth embodiment. For example, when forming the upper layer 302A using the material layer (AlGaN layer) of the nitride semiconductor layer 304 as an etching stopper layer, etching steps including the first and second etching steps described with reference to FIG. 6 may be performed. Further, when forming the lower layer 302B using the fourth nitride semiconductor layer 58 as an etching stopper layer, etching steps including a first etching step and a second etching step may be performed.

In the fourth embodiment, in-plane variations in etching grade are taken into consideration when arranging the nitride semiconductor layer 304 in the gate layer 302. In the step in which the gate layer 302 is formed, except for the region of the gate layer 302, the entire fifth nitride semiconductor layer 60 needs to be etched to expose the upper surface of the fourth nitride semiconductor layer 58. However, the fifth nitride semiconductor layer 60 may not be uniformly etched due to the in-plane variations in etching rate.

The fourth embodiment takes such in-plane variations into consideration and uses the material layer (AlGaN layer) of the nitride semiconductor layer 304 as an etching stopper layer when forming the upper layer 302A. In this case, the second etching step is performed to obtain a higher selective etching ratio. Further, the fourth nitride semiconductor layer 58 is used as an etching stopper layer when forming the lower layer 302B. In this case, the second etching step is performed to obtain a higher selective etching ratio. This method protects the fourth nitride semiconductor layer 58 (layer used to form second step layer 24) from damages resulting from the etching process that forms the gate layer 302.

The fourth embodiment is an example in which a single nitride semiconductor layer 304 is arranged in the gate layer 302. Nevertheless, the gate layer 302 may be divided into three or more divisional layers that are separated from one another, with each layer being, for example, a p-type GaN layer. In this case, a nitride semiconductor layer 304 (AlGaN layer) is arranged in contact with and between two adjacent ones of the divisional layers. Thus, there are more than one nitride semiconductor layers 304.

In addition to the advantages of the first embodiment, the fourth embodiment has the advantage described below.

(4-1) The nitride semiconductor layer 304 is arranged in the gate layer 302. In this structure, the upper layer 302A of the gate layer 302 is formed through etching using the material layer of the nitride semiconductor layer 304 (in this example, AlGaN layer) as an etching stopper layer, and the lower layer 302B of the gate layer 302 is formed through etching using the fourth nitride semiconductor layer 58 as an etching stopper layer. This method protects the fourth nitride semiconductor layer 58 (layer used to form second step layer 24) from damages resulting from the etching process that forms the gate layer 302.

### Fifth Embodiment

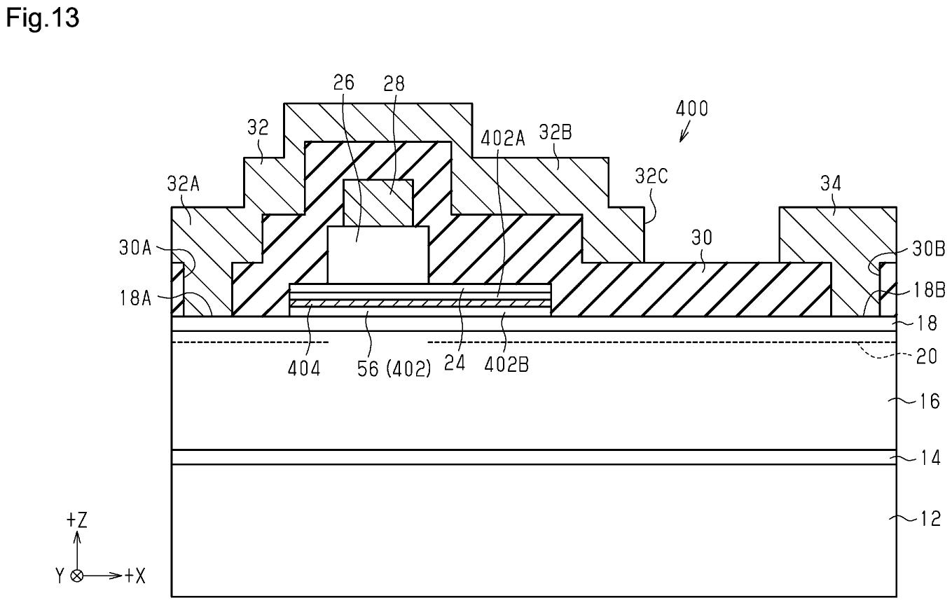

FIG. 13 is a schematic cross-sectional view illustrating an example nitride semiconductor device 400 in accordance with a fifth embodiment. In FIG. 13, same reference characters are given to those elements that are the same as the corresponding elements in the nitride semiconductor device 10 of the first embodiment. Elements that are the same as the corresponding elements in the first embodiment will not be described in detail. The description will focus on differences from the first embodiment.

The nitride semiconductor device 400 includes a first step layer 402 instead of the first step layer 22 (refer to FIG. 1) of the first embodiment. In the fifth embodiment, the first step layer 402 is a GaN layer.

The first step layer 402 is divided into two divisional layers, namely, an upper layer 402A and a lower layer 402B, that are separated from each other in the direction in which the first step layer 402 is stacked on the electron supplying layer 18. The nitride semiconductor device 400 further includes a nitride semiconductor layer 404 that is in contact with the upper layer 402A and the lower layer 402B and located between the upper layer 402A and the lower layer 402B. Each of the upper layer 402A and the lower layer 402B is, for example, a GaN layer, and the nitride semiconductor layer 404 is, for example, an AlGaN layer. Accordingly, the nitride semiconductor layer 404, which is an AlGaN layer, has a larger band gap than the upper layer 402A and the lower layer 402B, which are GaN layers.

In the fifth embodiment, the upper layer 402A and the lower layer 402B of the first step layer 402 are formed using the third nitride semiconductor layer 56 (GaN layer) as a material layer in the same manner as when forming the first step layer 22 as illustrated in FIG. 7. The nitride semiconductor layer 404 may be formed, for example, by using an AlGaN layer as a material layer in the same manner as the fourth nitride semiconductor layer 58 (AlGaN layer) illustrated in FIG. 6.

In the fifth embodiment, a GaN layer is the material layer of the nitride semiconductor layer 404 and used as the etching stopper layer. The step of forming the first step layer 402 of FIG. 13 will now be described with reference to FIG. 7. First, the third nitride semiconductor layer 56 (portion corresponding to upper layer 402A) is etched using the material layer (AlGaN layer) of the nitride semiconductor layer 404 as an etching stopper layer to form the upper layer 402A. Then, the nitride semiconductor layer 404 is formed. In the same manner as FIG. 7, the third nitride semiconductor layer 56 (portion corresponding to lower layer 402B) is then etched using the fourth nitride semiconductor layer 58 as an etching stopper layer to form the lower layer 402B.

The etching process used to form the first step layer 22 of the first embodiment (FIG. 7) may be applied as the etching process used to form the first step layer 402 of the fourth embodiment. For example, when forming the upper layer 402A using the material layer (GaN layer) of the nitride semiconductor layer 404 as an etching stopper layer, etching steps including the first and second etching steps described with reference to FIG. 7 may be performed. Further, when forming the lower layer 402B using the fourth nitride semiconductor layer 58 as an etching stopper layer, etching steps including a first etching step and a second etching step may be performed.

In the fifth embodiment, in-plane variations in etching grade are taken into consideration when arranging the nitride semiconductor layer 404 in the middle of the first step layer 402. In the step in which the first step layer 402 is formed, except for the region of the first step layer 402, the entire third nitride semiconductor layer 56 needs to be etched to expose the upper surface of the second nitride semiconductor layer 54. However, the third nitride semiconductor layer 56 may not be uniformly etched due to the in-plane variations in etching rate.

The fifth embodiment takes such in-plane variations into consideration and uses the material layer (AlGaN layer) of the nitride semiconductor layer 404 as an etching stopper layer when the upper layer 402A is formed. In this case, the second etching step is performed to obtain a higher selective etching ratio. Further, the second nitride semiconductor layer 54 is used as an etching stopper layer when the lower layer 402B is formed. In this case, the second etching step is performed to obtain a higher selective etching ratio. This method protects the second nitride semiconductor layer 54 (layer used to form electron supplying layer 18) from damages resulting from the etching process that forms the first step layer 402.

The fifth embodiment is an example in which a single nitride semiconductor layer 404 is arranged in the first step layer 402. Nevertheless, the first step layer 402 may be divided into three or more divisional layers that are separated apart from one another, with each layer being, for example, an AlGaN layer. In this case, a nitride semiconductor layer 404 (AlGaN layer) is arranged in contact with and between two adjacent ones of the divisional layers. Thus, there are more than one nitride semiconductor layers 404.

In addition to the advantages of the first embodiment, the fifth embodiment has the advantage described below.

(5-1) The nitride semiconductor layer 404 is arranged in the first step layer 402. In this structure, the upper layer 402A of the first step layer 402 is formed through etching using the material layer of the nitride semiconductor layer 404 (in this example, AlGaN layer) as an etching stopper layer, and the lower layer 402B of the first step layer 402 is formed through etching using the second nitride semiconductor layer 54 as an etching stopper layer. This method protects the second nitride semiconductor layer 54 (layer used to form electron supplying layer 18) from damages resulting from the etching process that forms the first step layer 402.

Example of Formation Pattern of Nitride Semiconductor Device.

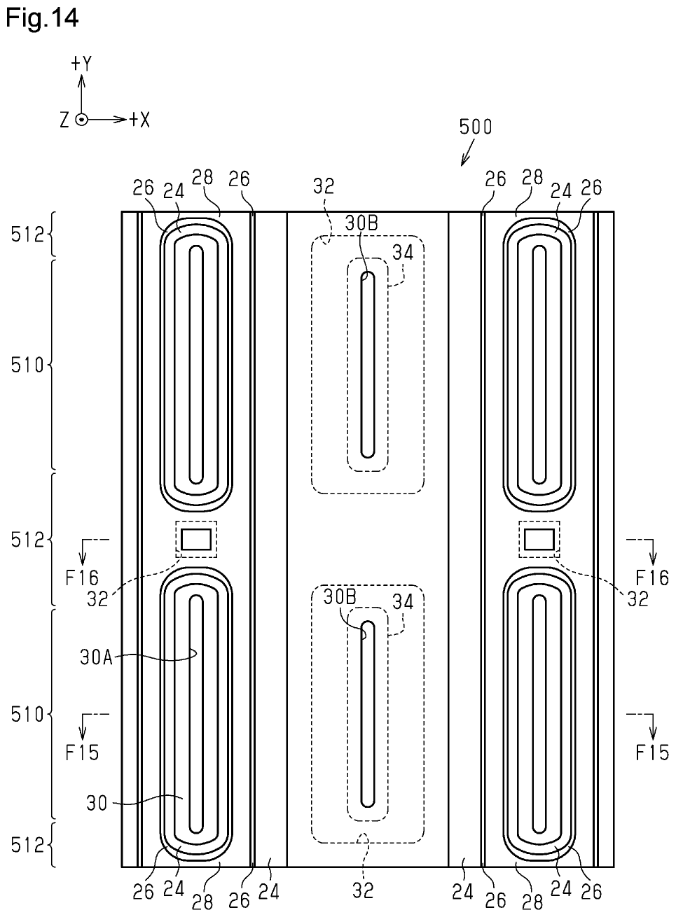

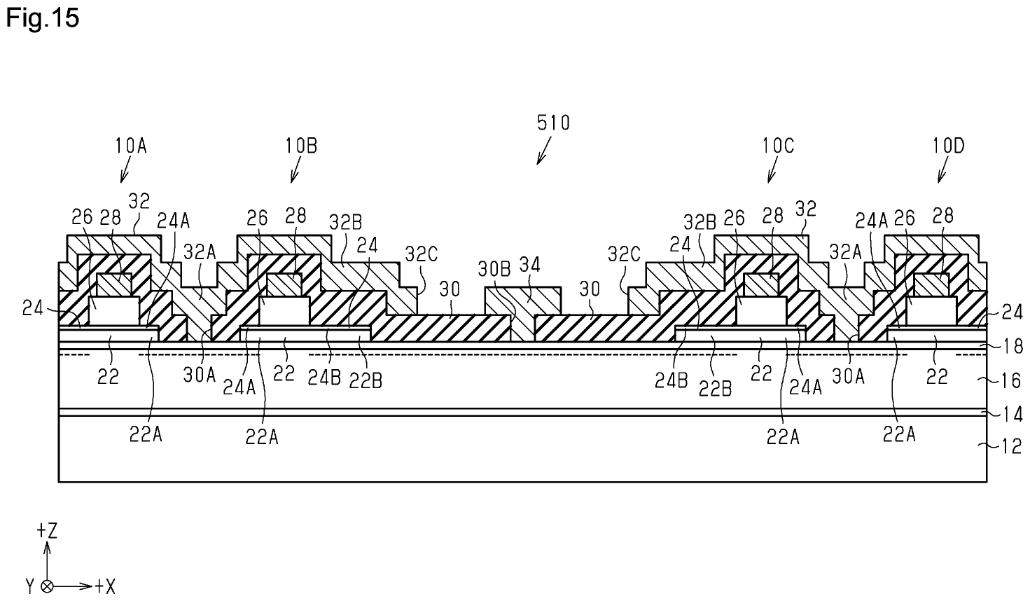

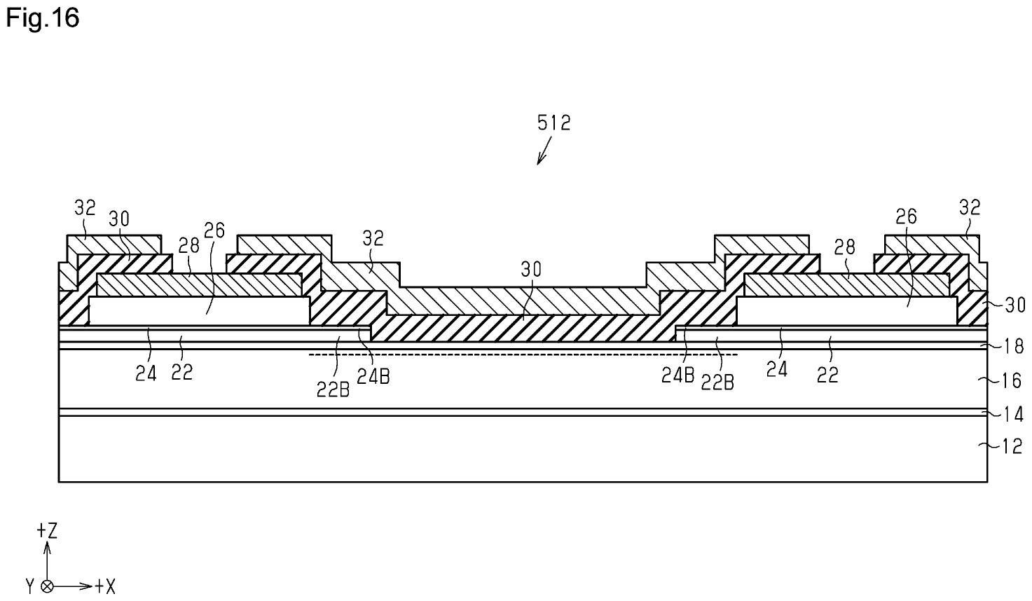

FIG. 14 is a schematic plan view illustrating an example formation pattern 500 of the nitride semiconductor device 10 illustrated in FIG. 1. FIG. 15 is a schematic cross-sectional view of an active region 510 taken along line F15-F15 in FIG. 14, and FIG. 16 is a schematic cross-sectional view of a non-active region 512 taken along line F16-F16 in FIG. 14. To facilitate understanding, in FIGS. 14 to 16, same reference characters are given to those elements that are the same as the corresponding elements illustrated in FIG. 1. To simplify the drawing, in FIG. 14, the source electrode 32 and the drain electrode 34 are illustrated in broken lines.

As illustrated in FIG. 14, the formation pattern 500 includes active regions 510, which contribute to transistor operations, and non-active regions 512, which do not contribute to transistor operations. An active region refers to a region where current flows between the source and the drain when voltage is applied to the gate electrode 28.

As illustrated in FIG. 15, the active region 510 includes a plurality of (four in the example of FIG. 15) nitride semiconductor devices (HEMT) 10A to 10D continuously formed in the X-axis direction. Each of the nitride semiconductor devices 10A to 10D have the same structure as the nitride semiconductor device 10 of FIG. 1.

In the example of FIG. 15, the nitride semiconductor devices 10A and 10B are laid out so that the source side extensions 22A and 24A of the first and second step layers 22 and 24 in the nitride semiconductor device 10A are opposed to the source side extensions 22A and 24A of the first and second step layers 22 and 24 in the nitride semiconductor device 10B with the source electrode portion 32A located in between. The nitride semiconductor devices 10C and 10D are also laid out so as to have the same arrangement relationship. The nitride semiconductor devices 10B and 10C are laid out so that the drain side extensions 22B and 24B of the first and second step layers 22 and 24 in the nitride semiconductor device 10B are opposed to the drain side extensions 22B and 24B of the first and second step layers 22 and 24 in the nitride semiconductor device 10C with the drain electrode 34 located in between. As illustrated in FIG. 16, the drain electrode 34 is not formed in the non-active region 512, and the passivation layer 30 is formed continuously with the source electrode 32 in the X-axis direction. As illustrated in FIG. 14, the second step layer 24, the gate layer 26, the gate electrode 28, and the source electrode 32 are formed continuously in the active region 510 and the non-active region 512 in the Y-axis direction. Although not illustrated in the drawings, the first step layer 22 is also formed continuously in the active region 510 and the non-active region 512.

As illustrated in FIGS. 14 to 16, the first and second step layers 22 and 24 (first step layer 22 not illustrated in FIG. 14) extend outward from the gate layer 26 in plan view. For example, in each of the active region 510 and the non-active region 512, the first and second step layers 22 and 24 extend outward from the entire periphery of the gate layer 26. In other words, in the XY plane, the first and second step layers 22 and 24 extend outward from the gate layer 26 in each of the positive X-axis direction, the negative X-axis direction, the positive Y-axis direction, and the negative Y-axis direction. In this manner, the first and second step layers 22 and 24 have a larger area than the gate layer 26 in plan view. This allows the holes in the first and second step layers 22 and 24 to be diffused in the Y-axis direction in addition to the X-axis direction. The formation pattern 500 illustrated in FIG. 14 may be applied to the nitride semiconductor devices 100, 200, 300, and 400 illustrated in FIGS. 10 to 13.

Further Example of Formation Pattern of Nitride Semiconductor Device

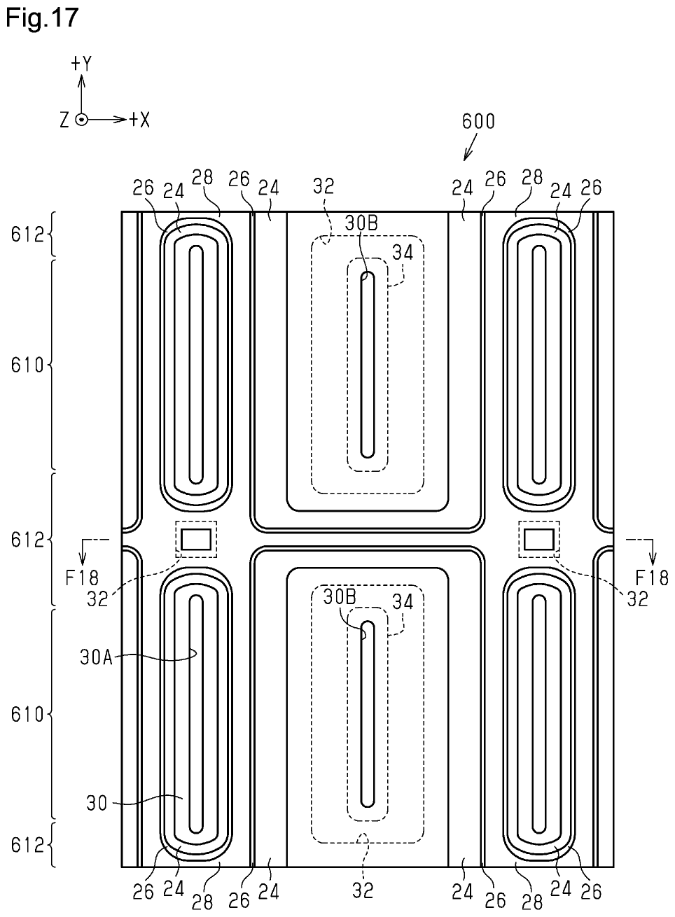

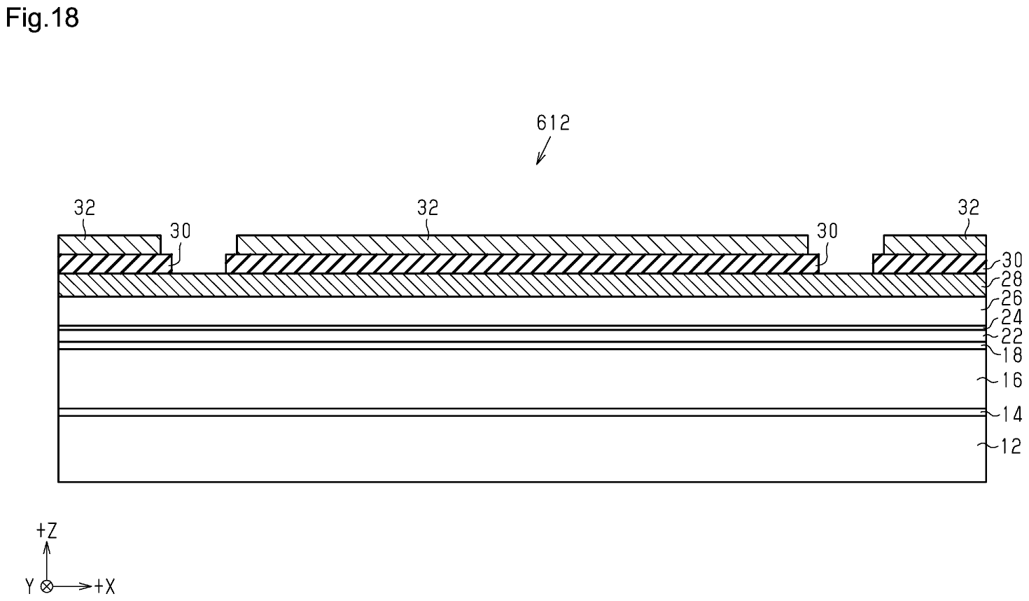

FIG. 17 is a schematic plan view illustrating an example formation pattern 600 of the nitride semiconductor device 10 illustrated in FIG. 1. FIG. 18 is a schematic cross-sectional view of a non-active region taken along line F18-F18 in FIG. 17. To facilitate understanding, in FIGS. 17 and 18, same reference characters are given to those elements that are the same as the corresponding elements illustrated in FIG. 1. To simplify the drawing, in FIG. 17, the source electrode 32 and the drain electrode 34 are illustrated in broken lines.

In the same manner as the formation pattern 500 of FIG. 14, the formation pattern 600 includes an active region 610 and a non-active region 612. The layout of the nitride semiconductor device 10 in the active region 610 is similar to that illustrated in FIG. 15.

As illustrated in FIGS. 17 and 18, in the non-active region 612, the first and second step layers 22 and 24 (first step layer 22 not illustrated in FIG. 17), the gate layer 26, the gate electrode 28, the passivation layer 30, and the source electrode 32 are formed continuously in the X-axis direction. Accordingly, in the non-active region 612, the GaN layer forming the first step layer 22 continuously covers the AlGaN layer forming the electron supplying layer 18 in the X-axis direction. Further, in the non-active region 612, the AlGaN layer forming the second step layer 24 continuously covers the first step layer 22 (AlGaN layer) in the X-axis direction, the gate layer 26 continuously covers the second step layer 24, and the gate electrode 28 continuously covers the gate layer 26.

In this manner, the first and second step layers 22 and 24 formed in the non-active region 612 of the formation pattern 600 have a larger area than the formation pattern 500 of FIG. 14 (refer to FIGS. 16 and 18). Thus, the hole diffusion effect of the nitride semiconductor device 10 in the active region 610 is higher than when using the formation pattern 500 of FIG. 14. Further, the gate electrode 28 formed in the non-active region 612 of the formation pattern 600 has a larger area than the formation pattern 500 of FIG. 14. This reduces the gate wiring resistance. The formation pattern 600 illustrated in FIG. 17 may be applied to the nitride semiconductor devices 100, 200, 300, and 400 illustrated in FIGS. 10 to 13.

In the same manner as FIG. 14, in the example of FIG. 17, in each of the active region 610 and the non-active region 612, the first and second step layers 22 and 24 extend outward from the entire periphery of the gate layer 26 in plan view. In this manner, the first and second step layers 22 and 24 have a larger area than the gate layer 26 in plan view. This allows the holes in the first and second step layers 22 and 24 to be diffused in the Y-axis direction in addition to the X-axis direction.

### Modified Examples

The above embodiments may be modified as described below. The above-described embodiments and the modified examples described below may be combined as long as there is no technical contradiction.

In the first step layer 22 of the first embodiment, the width W2 of the drain side extension 22B may be less than or equal to the width W1 of the source side extension 22A. In this case, the width W4 of the drain side extension 24B is less than or equal to the width W3 of the source side extension 24A in the second step layer 24 so that the drain side extension 24B of the second step layer 24 is formed on the drain side extension 22B of the first step layer 22 and the source side extension 24A of the second step layer 24 is formed on the source side extension 22A of the first step layer 22. The second embodiment (FIG. 10), the fourth embodiment (FIG. 12), and the fifth embodiment (FIG. 13) may be modified in the same manner.

The first step layer 22 of the first embodiment may be less the source side extension 22A and include only the drain side extension 22B. In this case, the second step layer 24 is also less the source side extension 22A and includes only the drain side extension 22B. Alternatively, the first step layer 22 of the first embodiment may be less the drain side extension 22B and include only the source side extension 22A. In this case, the second step layer 24 is also less the drain side extension 22B and includes only the source side extension 22A. The second embodiment (FIG. 10), the fourth embodiment (FIG. 12), and the fifth embodiment (FIG. 13) may be modified in the same manner.

In the second step layer 24 of the first embodiment, the source side extension 24A may be formed so that its thickness is gradually reduced from the base 24C in the negative X-axis direction toward the source contact 18A. Further, the drain side extension 24B may be formed so that its thickness is gradually reduced from the base 24C in the positive X-axis direction toward the drain contact 18B. The second embodiment (FIG. 10), the fourth embodiment (FIG. 12), and the fifth embodiment (FIG. 13) may be modified in the same manner.

In the first embodiment, the source side extension 24A of the second step layer 24 may be formed on part of the source side extension 22A of the first step layer 22. For example, the source side extension 24A may be formed on only part of the upper surface of the source side extension 22A in the vicinity of the base 24C. In the same manner, the drain side extension 24B of the second step layer 24 may be formed on part of the drain side extension 22B of the first step layer 22. For example, the drain side extension 24B may be formed on only part of the upper surface of the drain side extension 22B in the vicinity of the base 24C.

The gate electrode 28 only needs to be formed on at least part of the gate layer 26. For example, in each of the embodiments, the gate electrode 28 may be formed on the entire gate layer 26.

In this specification, the word “on” includes the meaning of “above” in addition to the meaning of “on” unless otherwise described in the context. Accordingly, the phrase of “first layer formed on second layer” may mean that the first layer is formed directly contacting the second layer in one embodiment and that the first layer is arranged above the second layer without contacting the second layer in another embodiment. Thus, the word “on” will also allow for a structure in which another layer is arranged between the first layer and the second layer. For example, in each of the above embodiments, the electron supplying layer 18 is formed on the electron transfer layer 16. This means that an intermediate layer may be located between the electron supplying layer 18 and the electron transfer layer 16 to stably form the 2DEG 20.

The Z-axis direction as referred to in this specification does not necessarily have to be the vertical direction and does not necessarily have to fully coincide with the vertical direction. Accordingly, in the structures disclosed above (e.g., structure illustrated in FIG. 1), upward and downward in the Z-axis direction as referred to in this specification are not limited to upward and downward in the vertical direction. For example, the X-axis direction may be the vertical direction. Alternatively, the Y-axis direction may be the vertical direction.

Clauses

Technical concepts that can be understood from each of the above embodiments and modified examples will now be described. The reference characters used to denote elements of the embodiments are illustrated in parenthesis for the corresponding elements of the clauses described below. The reference characters are given as examples to aid understanding and not intended to limit elements to the elements denoted by the reference characters.

Clause A1

A nitride semiconductor device, including:

an electron transfer layer (16) formed from a nitride semiconductor;

an electron supplying layer (18) formed on the electron transfer layer (16), the electron supplying layer (18) formed from a nitride semiconductor having a band gap that is larger than that of the electron transfer layer (16);

a first step layer (22; 402) formed on part of the electron supplying layer (18), the first step layer (22; 402) formed from a nitride semiconductor having a band gap that is smaller than that of the electron supplying layer (18);

a second step layer (24; 102; 202) formed on the first step layer (22; 402), the second step layer (24; 102; 202) formed from a nitride semiconductor having a band gap that is larger than that of the first step layer (22; 402);

a gate layer (26; 302) formed on part of the second step layer (24; 102; 202), the gate layer (26; 302) formed from a nitride semiconductor having a band gap that is smaller than that of the second step layer (24; 102; 202), the gate layer (26; 302) including an acceptor impurity;

a gate electrode (28) formed on the gate layer (26; 302); and

a source electrode (32) and a drain electrode (34) that are in contact with the electron supplying layer (18),

where the first step layer (22; 402) includes a first extension (22A/22B) that extends outward from the gate layer (26; 302) in plan view.

Clause A2

The nitride semiconductor device according to clause A1, where the first extension (22A/22B) extends outward from an entire periphery of the gate layer (26; 302) in plan view.

Clause A3

The nitride semiconductor device according to clause Al or A2, where the second step layer (24; 102) includes a second extension (24A/24B; 102A/102B) that extends outward from the gate layer (26; 302) in plan view and the second extension is formed on the first extension (22A/22B).

Clause A4

The nitride semiconductor device according to clause 3, where the second extension (24A/24B; 102A/102B) extends outward from an entire periphery of the gate layer (26; 302) in plan view.

Clause A5

The nitride semiconductor device according to any one of clauses A1 to A4, further including a passivation layer (30) formed on the electron supplying layer (18) and covering the first step layer (22; 402), the second step layer (24; 102; 202), the gate layer (26; 302), and the gate electrode (28).

Clause A6

The nitride semiconductor device according to clause A5, where:

the passivation layer (30) includes a source contact hole (30A) and a drain contact hole (30B) that respectively expose part of an upper surface of the electron supplying layer (18) as a source contact (18A) and a drain contact (18B);

the first extension (22A/22B) includes
a first source side extension (22A) extending outward from the gate layer (26; 302) toward the source contact (18A) in plan view, and
a first drain side extension (22B) extending outward from the gate layer (26; 302) toward the drain contact (18B) in plan view; and

the first step layer (22; 402) further includes a first base (22C) arranged downward from the gate layer (26; 302) and located between the first source side extension (22A) and the first drain side extension (22B).

Clause A7

The nitride semiconductor device according to clause A3 or A4, further including:

a passivation layer (30) that is formed on the electron supplying layer (18), covers the first step layer (22; 402), the second step layer (24; 102; 202), the gate layer (26; 302), and the gate electrode (28), and includes a source contact hole (30A) and a drain contact hole (30B) that respectively expose part of an upper surface of the electron supplying layer (18) as a source contact (18A) and a drain contact (18B);

the first extension (22A/22B) includes
a first source side extension (22A) extending outward from the gate layer (26; 302) toward the source contact (18A) in plan view, and
a first drain side extension (22B) extending outward from the gate layer (26; 302) toward the drain contact (18B) in plan view;

the first step layer (22; 402) further includes a first base (22C) arranged downward from the gate layer (26; 302) and located between the first source side extension (22A) and the first drain side extension (22B);

the second step extension (24A/24B; 102A/102B) includes
a second source side extension (24A; 102A) formed on the first source side extension (22A) and extending outward from the gate layer (26; 302) toward the source contact (18A) in plan view, and
a second drain side extension (24B; 102B) formed on the first drain side extension (22B) and extending outward from the gate layer (26; 302) toward the drain contact (18B) in plan view; and

the second step layer (24; 102; 202) further includes a second base (24C; 102C) arranged downward from the gate layer (26; 302) and located between the second source side extension (24A; 102A) and the second drain side extension (24B; 102B).

Clause A8

The nitride semiconductor device according to clause A7, where:

the first source side extension (22A) and the second source side extension (24A; 102A) each have a same width (W1, W3) in a direction extending toward the source contact (18A); and

the first drain side extension (22B) and the second drain side extension (24B; 102B) each have a same width (W2, W4) in a direction extending toward the drain contact (18B).

Clause A9

The nitride semiconductor device according to clause A7 or A8, where the second source side extension (24A) and the second drain side extension (24B) each have a thickness (D2) that is the same as that of the second base (24C).

Clause A10

The nitride semiconductor device according to any one of clauses A6 to A9, where the first source side extension (22A) and the first drain side extension (22B) each have a thickness (D1) that is the same as that of the first base (22C).

Clause A11

The nitride semiconductor device according to clause A7 or A8, where the second source side extension (102A) and the second drain side extension (102B) each have a thickness that is smaller than that of the second base (102C).

Clause A12

The nitride semiconductor device according to clause A1 or A2, where:

the first step layer (22; 402) further includes a base (22C) arranged downward from the gate layer (26; 302);

the first extension (22A/22B) extends from the base (22C); and

the second step layer (202) is formed on only the base (22C).

Clause A13

The nitride semiconductor device according to any one of clauses A1 to A12, where the second step layer (24; 102; 202) has a thickness (D2) that is smaller than that of the electron supplying layer (18) and a band gap that is smaller than that of the electron supplying layer (18).

Clause A14

The nitride semiconductor device according to any one of clauses A1 to A13, wherein at least one of the first step layer (22; 402) and the second step layer (24; 102; 202) includes an acceptor impurity.

Clause A15

The nitride semiconductor device according to any one of clauses A1 to A14, where the first step layer (22; 402) has a thickness (D1) that is smaller than that of the gate layer (26; 302).

Clause A16

The nitride semiconductor device according to any one of clauses A1 to A15, where the gate layer (302) includes two or more divisional layers (302A, 302B) separated from each other in a direction in which the gate layer (302) is stacked on the second step layer (24; 102; 202), the nitride semiconductor device further including:

one or more nitride semiconductor layers (304), each located between two adjacent ones of the two or more divisional layers (302A, 302B) of the gate layer (302) and having a band gap that is larger than that of each of the divisional layers (302A, 302B) of the gate layer (302).

Clause A17

The nitride semiconductor device according to any one of clauses A1 to A16, where the first step layer (402) includes two or more divisional layers (402A, 402B) separated from each other in a direction in which the first step layer (402) is stacked on the electron supplying layer (18), the nitride semiconductor device further comprising:

one or more nitride semiconductor layers (404), each located between two adjacent ones of the two or more divisional layers (402A, 402B) of the first step layer (402) and having a band gap that is larger than that of each of the divisional layers (402A, 402B) of the first step layer (402).

Clause A18

The nitride semiconductor device according to any one of clauses A1 to A17, where:

the electron transfer layer (16) is a GaN layer;

the electron supplying layer (18) is an AlGaN layer;

the first step layer (22; 402) is a GaN layer;

the second step layer (24; 102; 202) is an AlGaN layer having an Al composition that is lower than that of the electron supplying layer (18); and

the gate layer (26; 302) is a GaN layer including at least one of Mg and Zn as the acceptor impurity.

Clause A19

The nitride semiconductor device according to clause A18, where:

the electron supplying layer (18) is an AlₓGa₁₋ₓN layer (0.1<x<0.3); and

the second step layer (24; 102; 202) is an Al_{y}Ga_{1-y}N layer (0.05<y<x).

Clause A20

The nitride semiconductor device according to clause A18 or A19, where at least one of the first step layer (22; 402) and the second step layer (24; 102; 202) includes at least one of Mg and Zn as the acceptor impurity.

Clause A21

The nitride semiconductor device according to any one of clauses A1 to A20, where the electron supplying layer (18) has a thickness (D4) of 20 nm or less, and the second step layer (24; 102; 202) has a thickness (D2) of 10 nm or less.

Clause A22

The nitride semiconductor device according to clause A21, where the electron supplying layer (18) has a thickness (D4) of 15 nm or less, and the second step layer (24; 102; 202) has a thickness (D2) of 7 nm or less.

Clause B1

A method for manufacturing a nitride semiconductor device, the method including: forming a first nitride semiconductor layer (52) that acts as an electron transfer layer (16);

forming, on the first nitride semiconductor layer (52), a second nitride semiconductor layer (54) that acts as an electron supplying layer (18) and has a band gap that is larger than that of the first nitride semiconductor layer (52);

forming, on the second nitride semiconductor layer (54), a third nitride semiconductor layer (56) that has a band gap that is smaller than that of the second nitride semiconductor (54);

forming, on the third nitride semiconductor layer (56), a fourth nitride semiconductor layer (58) that has a band gap that is larger than that of the third nitride semiconductor layer (56);

forming, on the fourth nitride semiconductor layer (58), a fifth semiconductor layer (60) that has a band gap that is smaller than that of the fourth nitride semiconductor (58) and includes an acceptor impurity;

forming a gate electrode (28) on the fifth nitride semiconductor layer (60);

forming a gate layer (26; 302) from the fifth nitride semiconductor layer (60) so that the gate electrode (28) is located on the gate layer (26; 302);

forming a first step layer (22; 402) from the third nitride semiconductor layer (56) after forming a second step layer (24; 102; 202) from the fourth nitride semiconductor layer (58), where the first step layer (22; 402) is formed located on part of the electron supplying layer (18), and the second step layer (24; 102; 202) is formed located on the first step layer (22; 402); and

forming a source electrode (32) and a drain electrode (34) that are in contact with the electron supplying layer (18),

where the forming a first step layer (22; 402) from the third nitride semiconductor layer (56) includes forming a first extension (22A/22B) on the first step layer (22; 402) so that the first extension (22A/22B) extends outward from the gate layer (26; 302) in plan view.

Clause B2

The method according to clause B 1, where the forming a second step layer (24; 102) from the fourth nitride semiconductor layer (58) includes forming a second extension (24A/24B; 102A/102B) on the second step layer (24; 102) so that the second extension (24A/24B; 102A/102B) extends outward from the gate layer (26; 302) in plan view.

Clause B3

The method according to clause B2, where:

the first extension (22A/22B) has a first extension width (W1/W2); and

the second extension (24A/24B; 102A/102B) includes a second extension width (W3/W4) that is equal to the first extension width (W1/W2).

Clause B4

The method according to any one of clauses B1 to B3, where:

the forming a gate layer (26) from the fifth nitride semiconductor layer (60) includes selectively etching the fifth nitride semiconductor layer (60) to form the gate layer (26; 302);

the selectively etching the fifth nitride semiconductor layer (60) includes
starting etching of the fifth nitride semiconductor layer (60) in a first etching step,
shifting from the first etching step to a second etching step before an upper surface of the fourth nitride semiconductor layer (58) becomes exposed, and
ending etching of the fifth nitride semiconductor layer (60) in the second etching step by using the fourth nitride semiconductor layer (58) as an etching stopper layer; and

the second etching step has an etching condition in which a selective etching ratio of the fifth nitride semiconductor layer (60) to the fourth nitride semiconductor layer (58) is higher than that of the first etching step.

Clause B5

The method according to clause B4, where:

the first etching step is a dry etching step using a gas mixture, in which a diluent gas is added to a chlorine gas, as a first etching gas;

the diluent gas includes a nitrogen-containing gas or an argon gas;

the second etching step is a dry etching step using a gas mixture, in which a selective ratio adjustment gas is added to a chlorine gas, as a second etching gas; and

the selective ratio gas is a fluorine-containing gas or an oxygen-containing gas.

Clause B6

The method according to clause B5, where:

the dry etching step of each of the first etching step and the second etching step is performed by using an inductively coupled plasma (ICP) etching device; and

an ion-induced power resulting from bias power of the inductively coupled plasma (ICP) etching device in the second etching step is set to less than five watts (W).

Clause B7

The method according to any one of clauses B4 to B6, where the selective etching ratio of the second etching step is set to 10 or greater.

Clause B8

The method according to any one of clauses B1 to B3, where:

the forming a first step layer (22) from the third nitride semiconductor layer (56) after forming a second step layer (24; 102; 202) from the fourth nitride semiconductor layer (58) includes
starting etching of the fourth nitride semiconductor layer (58) in a first etching step,
shifting from the first etching step to a second etching step before an upper surface of the second nitride semiconductor layer (54) corresponding to the electron travel layer (18) becomes exposed, and
ending etching of the third nitride semiconductor layer (56) in the second etching step by using the second nitride semiconductor layer (54) as an etching stopper layer; and

the second etching step has an etching condition in which a selective etching ratio of the third nitride semiconductor layer (56) to the second nitride semiconductor layer (54) is higher than that of the first etching step.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

1. A nitride semiconductor device, comprising:
an electron transfer layer formed from a nitride semiconductor;
an electron supplying layer formed on the electron transfer layer, the electron supplying layer formed from a nitride semiconductor having a band gap that is larger than that of the electron transfer layer;
a first step layer formed on part of the electron supplying layer, the first step layer formed from a nitride semiconductor having a band gap that is smaller than that of the electron supplying layer;
a second step layer formed on the first step layer, the second step layer formed from a nitride semiconductor having a band gap that is larger than that of the first step layer;
a gate layer formed on part of the second step layer, the gate layer formed from a nitride semiconductor having a band gap that is smaller than that of the second step layer, the gate layer including an acceptor impurity;
a gate electrode formed on the gate layer; and
a source electrode and a drain electrode that are in contact with the electron supplying layer,
wherein the first step layer includes a first extension that extends outward from the gate layer in plan view.

2. The nitride semiconductor device according to claim 1, wherein the first extension extends outward from an entire periphery of the gate layer in plan view.

3. The nitride semiconductor device according to claim 1, wherein the second step layer includes a second extension that extends outward from the gate layer in plan view and the second extension is formed on the first extension.

4. The nitride semiconductor device according to claim 3, wherein the second extension extends outward from an entire periphery of the gate layer in plan view.

5. The nitride semiconductor device according to claim 1, further comprising a passivation layer formed on the electron supplying layer and covering the first step layer, the second step layer, the gate layer, and the gate electrode.

6. The nitride semiconductor device according to claim 5, wherein:
the passivation layer includes a source contact hole and a drain contact hole that respectively expose part of an upper surface of the electron supplying layer as a source contact and a drain contact;
the first extension includes
a first source side extension extending outward from the gate layer toward the source contact in plan view, and
a first drain side extension extending outward from the gate layer toward the drain contact in plan view; and
the first step layer further includes a first base arranged downward from the gate layer and located between the first source side extension and the first drain side extension.

7. The nitride semiconductor device according to claim 3, further comprising:
a passivation layer that is formed on the electron supplying layer, covers the first step layer, the second step layer, the gate layer, and the gate electrode, and includes a source contact hole and a drain contact hole that respectively expose part of an upper surface of the electron supplying layer as a source contact and a drain contact;
the first extension includes
a first source side extension extending outward from the gate layer toward the source contact in plan view, and
a first drain side extension extending outward from the gate layer toward the drain contact in plan view; and
the first step layer further includes a first base arranged downward from the gate layer and located between the first source side extension and the first drain side extension;
the second step extension includes
a second source side extension formed on the first source side extension and extending outward from the gate layer toward the source contact in plan view, and
a second drain side extension formed on the first drain side extension and extending outward from the gate layer toward the drain contact in plan view; and
the second step layer further includes a second base arranged downward from the gate layer and located between the second source side extension and the second drain side extension.

8. The nitride semiconductor device according to claim 7, wherein:
the first source side extension and the second source side extension each have a same width in a direction extending toward the source contact; and
the first drain side extension and the second drain side extension each have a same width in a direction extending toward the drain contact.

9. The nitride semiconductor device according to claim 7, wherein the second source side extension and the second drain side extension each have a thickness that is equal to or smaller than that of the second base.

10. The nitride semiconductor device according to claim 6, wherein the first source side extension and the first drain side extension each have a thickness that is the same as that of the first base.

11. The nitride semiconductor device according to claim 1, wherein:
the first step layer further includes a base arranged downward from the gate layer;
the first extension extends from the base; and
the second step layer is formed on only the base.

12. The nitride semiconductor device according to claim 1, wherein the second step layer has a thickness that is smaller than that of the electron supplying layer and a band gap that is smaller than that of the electron supplying layer.

13. The nitride semiconductor device according to claim 1, wherein at least one of the first step layer and the second step layer includes an acceptor impurity.

14. The nitride semiconductor device according to claim 1, wherein the first step layer has a thickness that is smaller than that of the gate layer.

15. The nitride semiconductor device according to claim 1, wherein the gate layer includes two or more divisional layers separated from each other in a direction in which the gate layer is stacked on the second step layer, the nitride semiconductor device further comprising:
one or more nitride semiconductor layers, each located between two adjacent ones of the two or more divisional layers of the gate layer and having a band gap that is larger than that of each of the divisional layers of the gate layer.

16. The nitride semiconductor device according to claim 1, wherein the first step layer includes two or more divisional layers separated from each other in a direction in which the first step layer is stacked on the electron supplying layer, the nitride semiconductor device further comprising:
one or more nitride semiconductor layers, each located between two adjacent ones of the two or more divisional layers of the first step layer and having a band gap that is larger than that of each of the divisional layers of the first step layer.

17. The nitride semiconductor device according to claim 1, wherein:
the electron transfer layer is a GaN layer;
the electron supplying layer is an AlGaN layer;
the first step layer is a GaN layer;
the second step layer is an AlGaN layer having an Al composition that is lower than that of the electron supplying layer; and
the gate layer is a GaN layer including at least one of Mg and Zn as the acceptor impurity.

18. The nitride semiconductor device according to claim 17, wherein:
the electron supplying layer is an AlₓGa₁₋ₓN layer (0.1<x<0.3); and
the second step layer is an Al_{y}Ga_{1-y}N layer (0.05<y<x).

19. The nitride semiconductor device according to claim 17, wherein at least one of the first step layer and the second step layer includes at least one of Mg and Zn as the acceptor impurity.

20. The nitride semiconductor device according to claim 1, wherein the electron supplying layer has a thickness of 20 nm or less, and the second step layer has a thickness of 10 nm or less.
